(19) United States
(12) Patent Application Publication
(10) Pub. No.: US 2006/0194073 A1
(43) Pub. Date: Aug. 31, 2006

(54) Organic compound and organic electrolumiscent device

(76) Inventor: Masato Okada, Tokyo (JP)

Correspondence Address: Timothy J Keefer;Seyfarth Shaw, 55 East Monroe, Suite 4200, Chicago, IL, 60603, US

(21) Appl. No.: 10/548,984

(22) PCT Filed: Mar. 5, 2004
(86) PCT No.: PCT/JP04/02804

§ 371 Date: Sep. 7, 2005

(30) Foreign Application Priority Data
Mar. 7, 2003 (JP) 2003-062590
Mar. 5, 2004 (JP) 2004-062291

(51) Int. Cl. C09K 11/06; H01L 51/54; H05B 33/14

(52) U.S. Cl. 428/690; 428/917; 313/504; 257/40; 257/E51.044; 257/E51.05; 252/301.16; 548/440; 546/4; 544/225; 548/108; 313/506

(57) ABSTRACT

An object of the present invention is to provide an organic compound easy for coating in a coating process and capable of presenting a high luminous efficiency, as well as an organic electroluminescent element utilizing the organic compound and exhibiting the high luminous efficiency. The object is achieved by an organic compound represented by EM-X—CTM or (EM-X—CTM)-Y, wherein EM is a fluorescent light emitting material or phosphorescent light emitting material; CTM is a charge transporting material; X is a chemical bonding chain for bonding EM and CTM; and Y is a substituent introduced at any part of EM, CTM or X for improving at least solubility to a solvent. Furthermore, in an organic EL element provided with at least a pair of opposite electrodes and one or more organic compound layers sandwiched between the electrodes, the object is achieved by containing a compound represented by EM-X—CTM or (EM-X—CTM)-Y in at least one layer of the organic compound layers.

### TECHNICAL FIELD

The present invention relates to an organic compound and an organic electroluminescent element (hereinafter the term “electroluminescent” may be abbreviated as “EL”.). Particularly, it relates to an organic compound exhibiting high solubility to a solvent and exhibiting an improved luminescence property, and relates to an organic EL element provided with an organic compound layer comprising the organic compound.

### BACKGROUND ART

An organic EL element utilizing an electroluminescence of an organic compound material is a self light emission type device which emits light by giving an electric field to a fluorescent organic compound. The organic EL element has a various advantages including a wide view angle, a low driving voltage, high intensity (brightness), easiness of a fabrication because of less constitutional layers than a liquid crystal element, capability in reducing the apparatus thickness and so on. Thus the organic EL element is noticed as a next generation display element. Particularly, in comparison with an inorganic EL element, the organic EL element can remarkably lower the voltage to be impressed and thereby reduce an energy consumption. In addition, the EL element has easiness of size-reduction, and enables light emission from a plane and light emission of three primary colors. Thus, the organic EL element has been under an enthusiastic research and development.

For a structure of the organic EL element, a fundamental structure is “a positive electrode/a light emitting layer/a negative electrode”, and there are known other structures which are further provided with a hole injection transporting layer and/or an electron injection transporting layer as an occasion demands, such as “a positive electrode/a hole injection transporting layer/a light emitting layer/a negative electrode”, and “a positive electrode/a hole injection transporting layer/a light emitting layer/an electron injection transporting layer/a negative electrode”.

The organic EL element utilizes excited energy as light emission, which is taken from the energy in an excited state generated by a recombination of electrons and holes injected in the element. The generated excited state is considered to include 25% of singlet state and 75% of triplet state. In the organic EL element utilizing fluorescence, only the energy of singlet state is utilized, and therefore inner quantum efficiency is disadvantageously restricted within 25% according to the principle.

Attentions are now imposed on an organic EL element utilizing phosphorescence. The organic EL element utilizing phosphorescence (may referred to as a phosphorescent organic EL element) can utilize the energy of triplet state as well as that of singlet state, and it enables the inner quantum efficiency to rise up to 100% according to the principle.

In the phosphorescent organic EL element, a light emitting material comprising metallic complex containing heavy metal such as platinum, iridium or the like is used as a dopant for emitting phosphorescence, and a host material is doped with such light emitting material to take the phosphorescent emission (e.g. M. A. Baldo et al., “Nature”, vol. 403, p. 750-753 (2000)).

Light emission by the phosphorescent dopant has relativity to the host material. Basic properties required to the host material include: a hole or charge transporting ability; a reduction potential of the host material higher than that of the phosphorescent dopant; an energy level of triplet state of the host material lower than the reduction potential of the dopant; or the like. In general, a low molecular weight material, CBP, namely 4,4′-Bis(Carbazol-9-yl)-biphenyl is preferably used (e.g. Japanese Patent Application Laid-open No. Hei 10-168443).

The phosphorescent element utilizing such a low molecular weight material can facilitate an optimization of a layered structure, and thereby give an expectation for an improved efficiency and an elongated life. On the other hand, however, there is a problem of a deterioration of the element due to a crystallization or agglomeration of the organic layer over time, which has a great influence on a life of the element. Furthermore, the phosphorescent element must be fabricated by a vapor deposition process, which requires a large scale deposition apparatus and has a difficulty in a cost, and which has a further difficulty in preparing a substrate having a large surface area. There is a coating process of coating the dopant on the substrate using a solvent, which is a process capable of fabricating a large surface area display with a lower cost than that of the vacuum vapor deposition process. It is difficult, however, to utilize the conventional low molecular weight material in the coating process, because a uniform stable coating liquid can not be obtained and the film stability is low even if a film can be formed from the coating liquid, due to the low solubility and low dispersibility in the case that the coating liquid is prepared by dissolving or dispersing the conventional low molecular weight material into a solvent.

In order to solve these problems, a phosphorescent element capable of being formed by the coating process is recently developed. For example, there are reported (1) a method of coating a solution mixture of a high molecular host such as PVCz, namely polyvinyl carbazole, and a low molecular phosphorescent guest such as Ir (ppy)₃, namely tris-(2-phenyl-pyridinate-N, C^{2′}) iridium (III) complex (e.g. Japanese Patent Application Laid-Open No. 2001-257076), (2) a method of coating a solution of a high molecule which is obtained by copolymerizing a host molecular monomer and a guest molecular monomer (e.g. J.-S. Lee at el., Polymer Preprints 2001, 42 (2), p. 448-449(2001); Mitsunori SUZUKI, Seiji TOKITOU, NHK GIKEN R&D, No. 77, p. 34-41(2003)), (3) a method of coating a solution mixture of a low molecular host and a low molecular phosphorescent guest disposed at a center of a conjugated dendrimer (e.g. S.-C. Lo. et. al., Adv. Mater., vol. 14, No. 13-14, p. 975-979(2002)), and so on. Furthermore, there is also reported an organic EL element having an improved stability to oxygen or water (e.g. Japanese Patent Application Laid-Open No. 2002-543570).

### DISCLOSURE OF INVENTION

In the aforementioned reports, however, there is a problem of insufficient luminescence property or insufficient element life, although a film can be produced easily by spin-coating the solution. The reason why the luminescence property or element life is insufficient is considered that, in cases of reports (1) and (2), the high molecular host does not have an electron transporting function and thereby the coating solution essentially containing an electron transporting low molecular guest such as oxyziazole or triazole is used, and however this charge transporting low molecular guest tends to lead the deterioration or agglomeration. Furthermore, in the case of report (3), it is considered that the guest molecular has dendrons around the luminescence center, which contributes to a uniform dispersion of the guest molecular. On the other hand, it is considered that, due to such dendrons, a host and a guest which are most closely adjacent to each other can not always take an optimum intermolecular distance or optimum relative orientation, which may inhibit an efficient energy transfer.

The present invention has been achieved in order to solve the above-mentioned problems. It is therefore an object of the present invention to provide an organic compound suitable for coating in a coating process and capable of presenting a high luminous efficiency, as well as an organic electroluminescent element utilizing the organic compound and exhibiting the high luminous efficiency.

The inventor of the present invention found out the following facts, in course of studying the organic EL element suitable for coating in a coating process and exhibiting a high luminous efficiency. That is, there is found that easiness of coating and evenness in dispersion are improved by containing EM molecules and CTM molecules into a compound and binding them with a molecular chain having solubility to a solvent, and there is found that the intermolecular distance and the relative orientation between the host and guest, which are most closely adjacent to each other and which are bonded by the added molecular chain, can be optimized, and the luminous efficiency on recombination can be remarkably improved, in comparison with the conventional coating method. The present invention has been accomplished from these findings.

That is, an organic compound according to the first embodiment of the present invention is represented by the following general formula (1):
EM-X—CTM (1)
wherein, EM is a fluorescent light emitting material or phosphorescent light emitting material; CTM is a charge transporting material; and X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain.

Furthermore, an organic compound of the second embodiment of the present invention is represented by the following general formula (2):
(EM-X—CTM)-Y (2)
wherein, EM is a fluorescent light emitting material or phosphorescent light emitting material; CTM is a charge transporting material; X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain; and Y is a substituent introduced at any part of EM, CTM or X for improving at least solubility to a solvent, Y being selected from a group consisting of hydrogen atom, alkyl group, alkoxy group, alkylthio group, alkylsilyl group, alkylamino group, aryl group, arylalkyl group, arylalkoxyl group, arylalkynyl group, arylamino group, heterocyclic group, cyano group, nitro group, and halogen atoms.

Furthermore, an organic compound of the third embodiment of the present invention is represented by the following general formula (3): 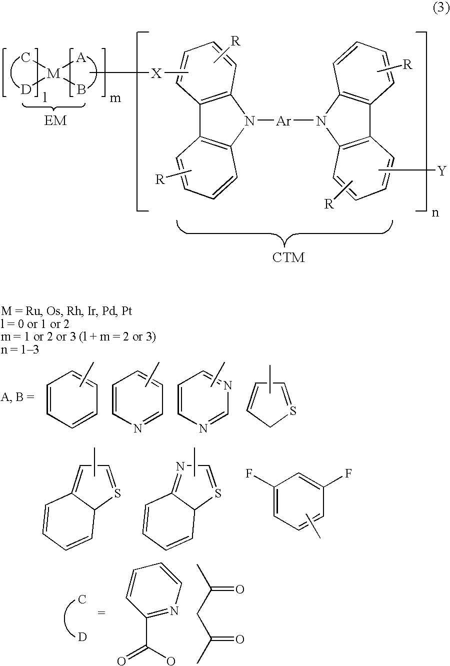
wherein, EM is a fluorescent light emitting material or phosphorescent light emitting material; CTM is a charge transporting material; Ar is a non-substituted or substituted arylene group or a non-substituted or substituted heterocyclic group; each R may be different or same, and selected from the group consisting of hydrogen atom, alkyl group, alkoxy group, alkylthio group, alkylsilyl group, alkylamino group, aryl group, arylalkyl group, arylalkoxy group, arylalkynyl group, arylamino group, heterocyclic group, cyano group, nitro group, and halogen atoms; X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain; and Y is a substituent optionally introduced as an occasion demands for improving at least solubility to a solvent, Y being selected from a group consisting of hydrogen atom, alkyl group, alkoxy group, alkylthio group, alkylsilyl group, alkylamino group, aryl group, arylalkyl group, arylalkoxyl group, arylalkynyl group, arylamino group, heterocyclic group, cyano group, nitro group, and halogen atoms.

The organic compounds according to these first to third embodiments are compounds represented by these general formulae (1) to (3), in which each light emitting material EM and each charge transporting material CTM are bonded by each chemical bonding chain X. These compounds tend to dissolve uniformly in the solvent or tend to disperse easily, due to a good solubility of the chemical bonding chain X. Thereby, it is possible to obtain a uniform luminescence property at each part on a material to be coated, because these organic compounds can disperse without agglomerating in the coating film, by applying a coating material containing any of these compounds onto the material to be coated. Furthermore, in these organic compounds of the present invention, their chemical bonding chain X optimizes the relative orientation and intermolecular distance between a host and a guest, which are most closely adjacent, and also acts as a barrier for preventing the charge migration. Thereby, it is possible to ensure the hopping conduction from the charge transporting material CTM to the light emitting material EM, and achieve further improved luminous efficiency when used for an organic EL element. Particularly, in the second and third embodiments, since they include each substituent Y, the solubility of the compounds can be improved, due to the effect of each substituent Y. Since each substituent Y acts so as to give a stereo hindrance to these compounds, this substituent Y can prevent the agglomeration of the compounds when these compounds dissolve or disperse in a solvent, and thereby can disperse these compounds uniformly, almost monodispersely, in a low or high molecular binder composing an organic compound layer. The uniform disperse of the compounds in the film or layer means a uniform light emission in a plane or surface, on the basis of injected charges, and thereby can contribute to the improved luminous efficiency.

In these organic compounds according to the first to third embodiments of the present invention, it is preferable that an intermolecular distance between the EM and the CTM is set at a predetermined distance at which solubility and/or hopping conduction of the organic compound can be maintained.

In these organic compounds according to the first to third embodiments of the present invention, it is preferable, for mainly a view point of the solubility, that AˆB is 3 Å or more, wherein an atom in EM bonded to X is referred to as an atom A, an atom in CTM bonded to X is referred to as an atom B, and a shortest distance sum of interatomic distances from the atom A to the atom B via a neighboring atom on X is referred to as AˆB.

Furthermore, it is preferable, for mainly a view point of ensuring the hopping conduction, that A−B is 2 Å to 50 Å, wherein an atom in EM bonded to X is referred to as an atom A, an atom in CTM bonded to X is referred to as an atom B, and a linear distance between the atom A and the atom B is referred to as A−B.

Furthermore, it is preferable, for mainly a view point of the solubility and ensuring the hopping conduction, that a ratio represented by (AˆB)/(A−B) is 1.1 to 20, wherein an atom in EM bonded to X is referred to as an atom A, an atom in CTM bonded to X is referred to as an atom B, a shortest distance sum of interatomic distances from the atom A to the atom B via a neighboring atom on X is referred to as AˆB, and a linear distance between the atom A and the atom B is referred to as A−B.

Furthermore, it is preferable, for mainly a view point of the solubility and ensuring the hopping conduction, that A−B is 2 Å to 50 Å and (AˆB)/(A−B) is 1.1 to 10, wherein an atom in EM bonded to X is referred to as an atom A, an atom in CTM bonded to X is referred to as an atom B, a shortest distance sum of interatomic distances from the atom A to the atom B via a neighboring atom on X is referred to as AˆB, and a linear distance between the atom A and the atom B is referred to as A−B.

Furthermore, for mainly a view point of optimizing the relative orientation and the intermolecular distance between a host and a guest, which are most closely adjacent, and acting as a barrier for preventing the charge migration, it is preferable that said X includes a cycloaliphatic compound, especially includes a cycloaliphatic compound represented by the following general formula (4).
Formula (4):

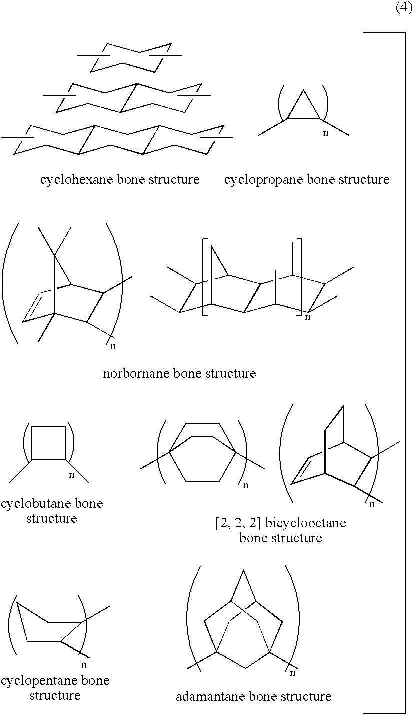

Furthermore, for a view point of achieving a thermally stable structure, it is preferable that said X comprises a hydrocarbon chain in which a hetero atom is not contained.

Furthermore, in the organic compounds according to the first to third embodiments of the present invention, it is preferable that (i) said EM is a fluorescent light emission colorant selected from a group consisting of a coumarin derivative, a quinolidine derivative, a quinacridon derivative, a pyrrolopyrrole derivative, a polycyclic aromatic hydrocarbon, a styrylbenzene derivative, polymethine derivative and a xanthene derivative; a fluorescent light emission metallic complex selected from a group consisting of a quinolinol complex derivative, a quinoline complex derivative, a hydroxyphenyl oxazole, a hydroxyphenyl thiazole and an azomethine metallic complex derivative; or a phosphorescent light emission transition metal complex selected from a group consisting of an iridium complex derivative and a platinum complex derivative, and (ii) said CTM is a hole transporting material selected from a group consisting of an aromatic tertiary amine derivative, starburst polyamines and a phthalocyanine metallic complex derivative; a charge transporting material selected from a group consisting of an aluminoquinolinol complex derivative, an oxadiazole derivative, a triazole derivative, a triazine derivative and a phenylquinoxalline derivative; or a hole charge transporting material selected from a carbazole biphenyl.

On the other hand, an organic EL element of the first embodiment of the present invention is an organic electroluminescent element provided with: at least a pair of opposite electrodes; and one or more organic compound layers sandwiched between the pair of opposite electrodes, wherein at least one layer of the organic compound layers contains an organic compound represented by the general formula (1) described above.

Furthermore, an organic EL element according to the second embodiment of the present invention is an organic electroluminescent element provided with: at least a pair of opposite electrodes; and one or more organic compound layers sandwiched between the pair of opposite electrodes, wherein at least one layer of the organic compound layers contains an organic compound represented by the general formula (2) described above.

Furthermore, an organic EL element according to the third embodiment of the present invention is an organic electroluminescent element provided with: at least a pair of opposite electrodes; and one or more organic compound layers sandwiched between the pair of opposite electrodes, wherein at least one layer of the organic compound layers contains an organic compound represented by the general formula (3) described above.

In these organic EL elements of the present invention, at least one layer of the organic compound layers contain any of the organic compounds of the present invention. The organic compounds according to the present invention, in which each light emitting material EM and each charge transporting material CTM are bonded by each chemical bonding chain X, tend to soluble uniformly in the solvent or tend to disperse easily, due to a good solubility of the chemical bonding chain X. Thereby, it is possible to obtain a uniform luminescence property at each part on a material to be coated, because these organic compounds can disperse without agglomerating in the coating film, by applying a coating material containing any of these compounds onto the material to be coated. Furthermore, in the case that the chemical bonding chain X includes a saturated hydrocarbon chain, a direct and spatial energy migration can be achieved between the charge transporting material CTM and the light emitting material EM, without passing any bridge (cross-linking) group. Therefore, it can present not only higher luminous efficiency, but also the light emission due to the EM. Particularly, in the second and third embodiments, since they include each substituent Y, the solubility of the compounds can be improved, due to the effect of each substituent Y. Since each substituent Y acts so as to give a stereo hindrance to these compounds, this substituent Y can prevent the agglomeration of the compounds when these compounds dissolve or disperse in a solvent, and thereby can disperse these compounds uniformly, almost monodispersely, in a low or high molecular binder composing an organic compound layer. The uniform disperse of the compounds in the film or layer means a uniform light emission in a plane or surface, on the basis of injected charges, and thereby can contribute to the improved luminous efficiency.

In these organic EL elements according to the first to third embodiments of the present invention, it is preferable that an intermolecular distance between the EM and the CTM is set at a predetermined distance at which solubility and/or hopping conduction of the organic compound can be maintained.

According to this invention, since the intermolecular distance between the light emitting material EM and the charge transporting material CTM is controlled to a predetermined length for ensuring the solubility of the compounds and/or the hopping conduction, the effect on these organic compound layers can be stable. In this case, in order to improve the solubility to a solvent, the chemical bonding chain X needs to be elongated, which may deteriorate the charge transporting property (charge migration property) between molecules. However, by adding each substituent Y for supplementing the solubility to a solvent, it is possible to achieve a chemical structure exhibiting a good charge transporting property. The length thereof is preferably controlled to 0.1 to 20 nm and an orientation, so that the light emitting material EM and the charge transporting material CTM easily perform the charge migration within the distance and the orientation. Particularly, it is preferable the chemical bonding chain X is a chemical bonding chain to fix the orientation of the EM and CTM, and has a rigid bone structure represented by the formula (4), namely, in which the possible stereo conformation is thermodynamically limited.

Furthermore, in these organic EL elements according to the first to third embodiments of the present invention, it is preferable that (i) said EM is a fluorescent light emission colorant selected from a group consisting of a coumarin derivative, a quinolidine derivative, a quinacridon derivative, a pyrrolopyrrole derivative, a polycyclic aromatic hydrocarbon, a styrylbenzene derivative, polymethine derivative and a xanthene derivative; a fluorescent light emission metallic complex selected from a group consisting of a quinolinol complex derivative, a quinoline complex derivative, a hydroxyphenyl oxazole, a hydroxyphenyl thiazole and an azomethine metallic complex derivative; or a phosphorescent light emission transition metal complex selected from a group consisting of an iridium complex derivative and a platinum complex derivative, and (ii) said CTM is a hole transporting material selected from a group consisting of an aromatic tertiary amine derivative, starburst polyamines and a phthalocyanine metallic complex derivative; a charge transporting material selected from a group consisting of an aluminoquinolinol complex derivative, an oxadiazole derivative, a triazole derivative, a triazine derivative and a phenylquinoxalline derivative and a carbazole biphenyl derivative.

According to this invention, it is possible to present an organic EL element having improved luminous efficiency.

Furthermore, in these organic EL elements according to the first to third embodiments of the present invention, it is preferable that the compound is mixed with or dispersed within a charge transporting low or high molecular weight material to form a light emitting layer. According to this invention, the compound having a good solubility and dispersibility can disperse uniformly in the charge transporting low or high molecular weight material, and form a light emitting layer without any agglomeration.

Furthermore, in these organic EL elements according to the first to third embodiments of the present invention, it is preferable that a charge transporting layer is disposed between the light emitting layer and a negative electrode (cathode), and a hole transporting layer is disposed between the light emitting layer and a positive electrode (anode).

### BRIEF DESCRIPTION OF DRAWINGS

FIG. 1 is alight emission spectrum of the organic EL element according to the present invention.

### BEST MODE FOR CARRYING OUT THE INVENTION

<Organic Compound>

Hereinafter, an organic compound of the present invention will be explained in detail.

The organic compound of the present invention is a compound represented by the following general formulae (1)-(3).

Formula (1):
EM-X—CTM (1)
Formulae (2):
(EM-X—CTM)-Y (2)

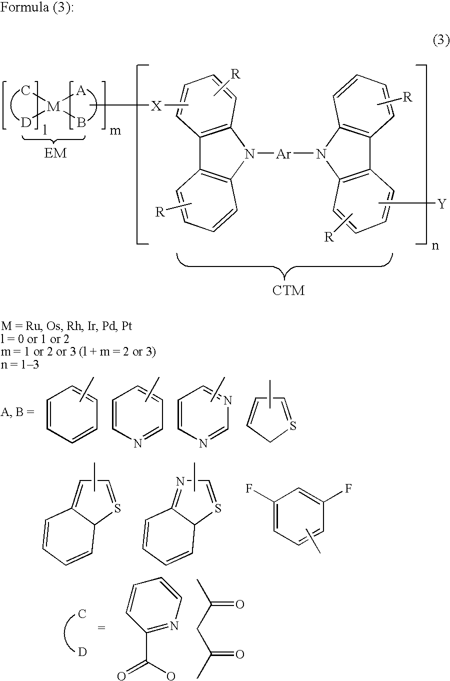

In the compound represented by the above general formulae (1) to (3), EM is a fluorescent light emitting material or phosphorescent light emitting material; CTM is a charge transporting material; and X is a chemical bonding chain for bonding EM and CTM; and Y is a substituent.

The fluorescent light emitting material may be a colorant material or a metallic complex material. For example, the colorant material may be: a polycyclic aromatic hydrocarbon such as a coumarin derivative, a DCM2 (quinolidine derivative), a quinacrydone derivative, a perylene, a rubrene and soon; a pyrene derivative; a pyrrolopyrrole derivative; a styrylbenzene derivative; a polymethine derivative; xanthene derivative and so on. Examples of them are shown below.

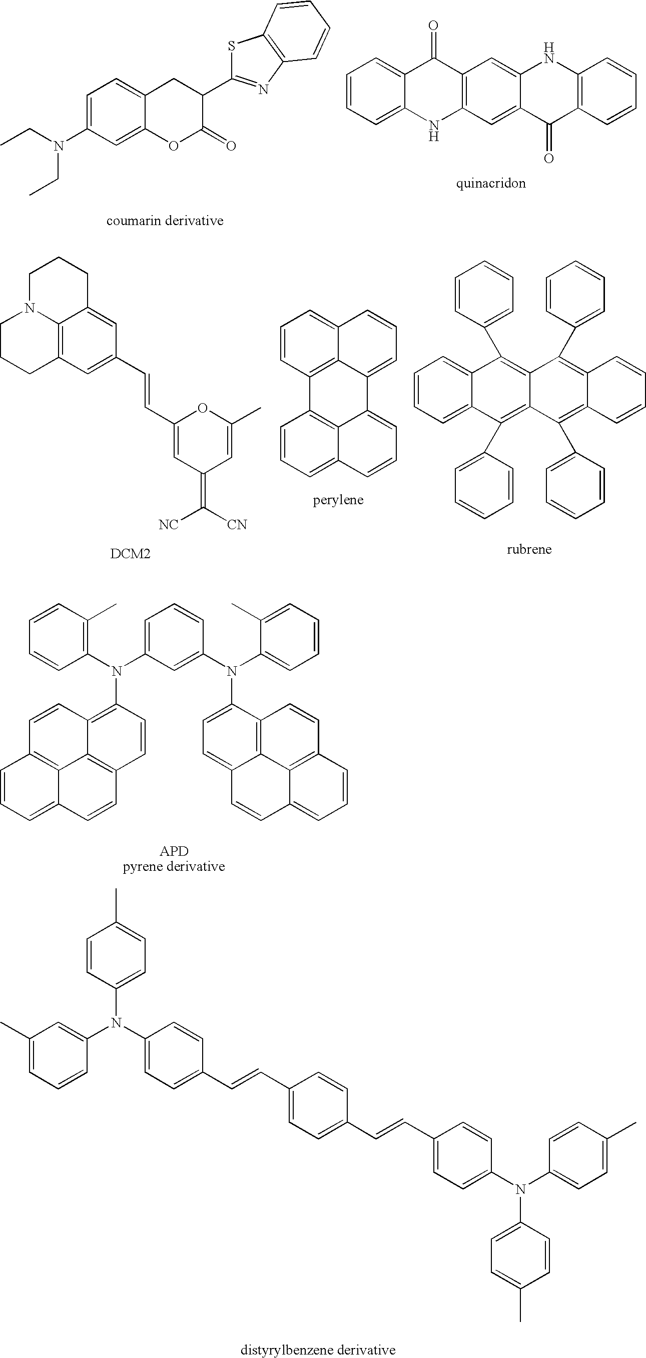

For example, the metallic complex material may be a quinolinol complex derivative such as Alq₃ (alminoquinolinol complex); a quinoline complex derivative such as Beq2 (beryllium-quinoline complex); and other materials such as a hydroxyoxazole, a hydroxyphenylthiazole, an azomethine metallic complex derivative and so on. Examples of them are shown below.

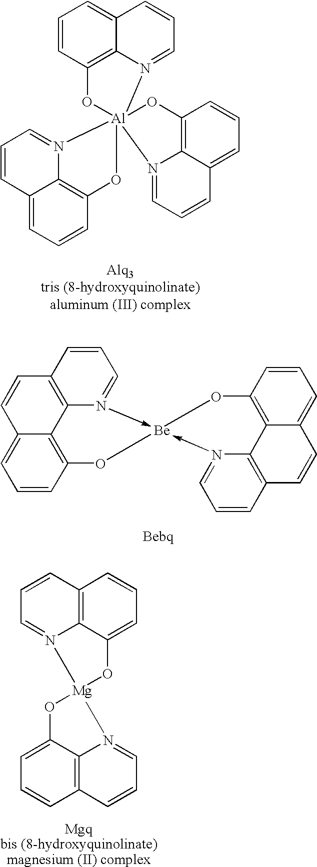

For example, the phosphorescent light emitting material may be a transition metal complex including an iridium complex derivative such as an Ir(ppy)₃; a platinum complex derivative such as PtOEP and so on.

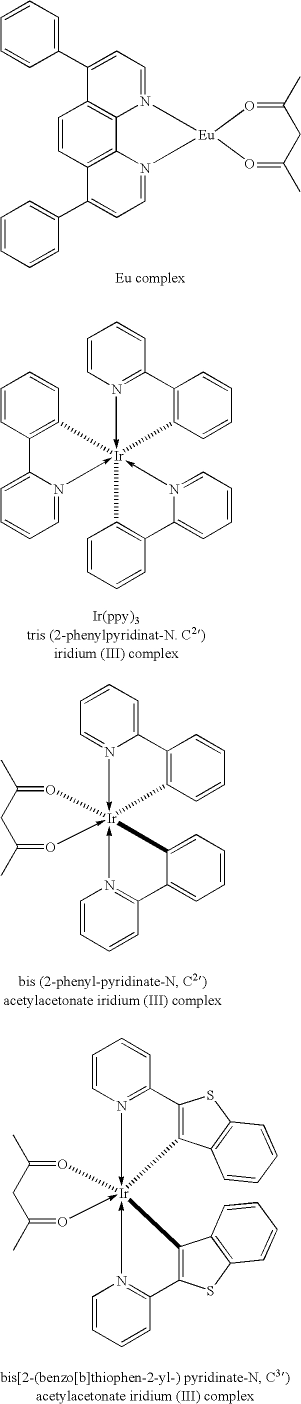

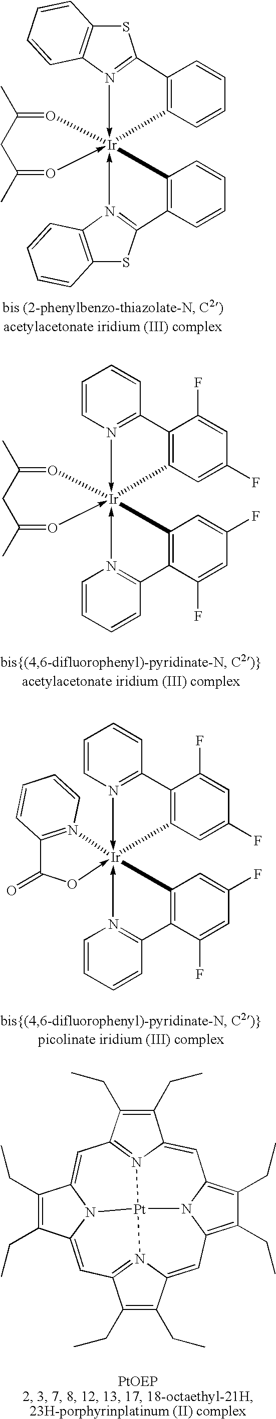

The charge transporting material CTM includes a hole transporting material, a charge transporting material, and a hole charge transporting material. For example, the hole transporting material may be an aromatic tertiary amine derivative, starburst polyamines, and a phthalocyanine metallic complex derivative. Examples of them are shown below.

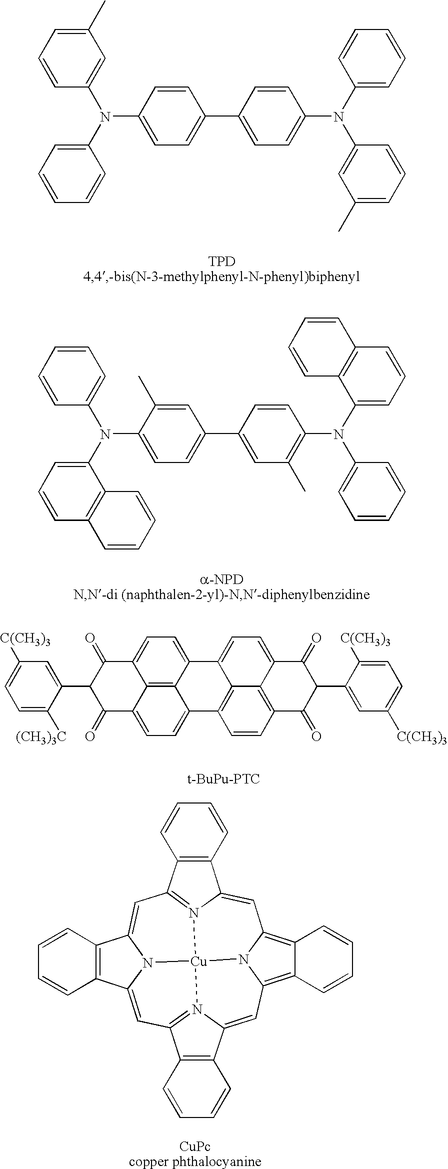

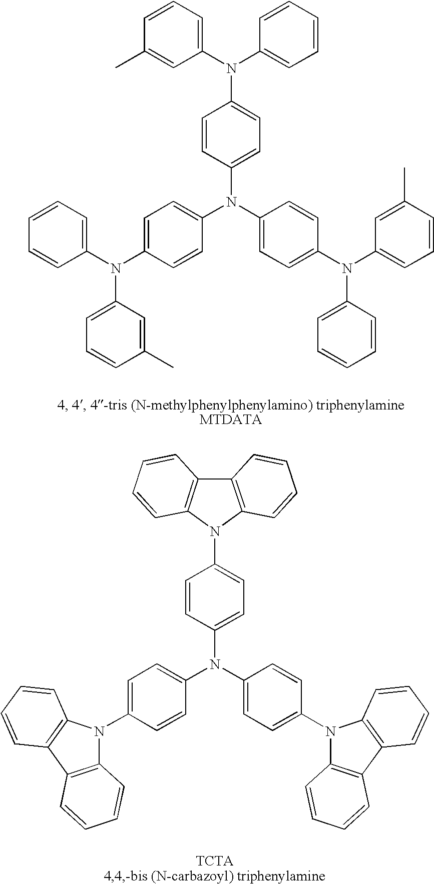

For example, the charge transporting material may be an Alq₃derivative, an oxadiazole derivative, a triazole derivative, an imidazole derivative, a triadine derivative, a phenylquinoxaline derivative. Examples of them are shown below.

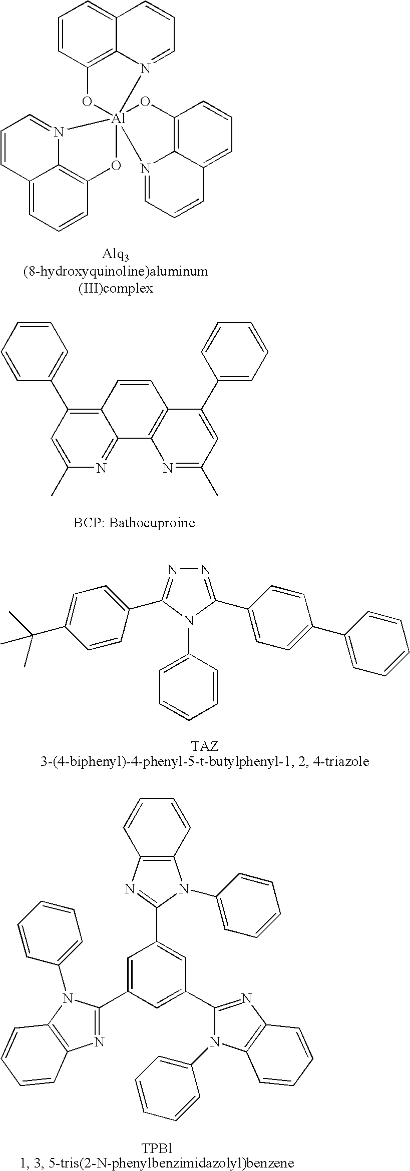

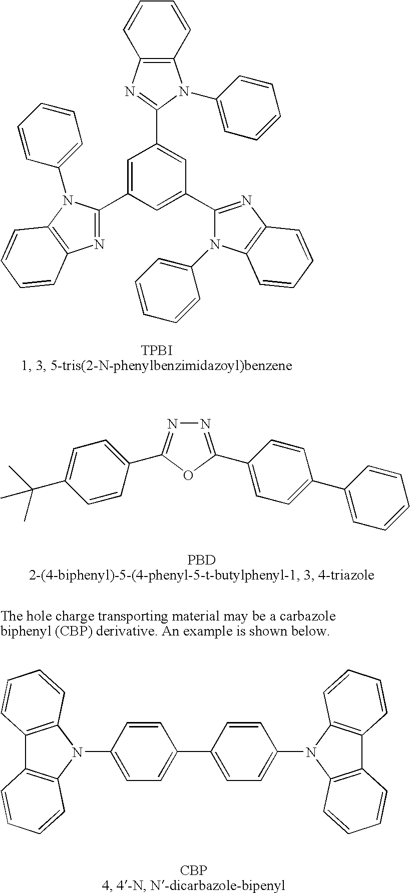

The chemical bonding chain X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain.

The hydrocarbon chain includes a saturated hydrocarbon such as —CH₂—, or an unsaturated hydrocarbon such as —CH═CH—. The carbon chain includes —C≡C—. Furthermore, in the hydrocarbon chain, a hetero atom such as O, S or the like may be included, and/or a hydrogen atom maybe substituted by a halogen atom such as a fluorine atom or the like. The cyclic hydrocarbon may be of a cycloaliphatic compound, or may be of an aromatic compound. The substituent which may be present on the cycle is preferably a straight or branched alkyl group. In the substituent, one or more methylene group, which are not adjacent, in the alkyl group may be substituted by —O—, —S—, —CO—, —CO—O—, —O—CO—, —CH═CH— or —C≡C—, and a hydrogen atom in the alkyl group may be substituted by a fluorine atom.

The chemical bonding chain X is preferably electrically neutral and preferably has a structure to cut a conjugated system made of EM and CTM. It is preferable that atoms which bond to EM and CTM at least do not contain any unsaturated bond.

For example, the straight or branched chemical bonding chain X may be: a straight or branched saturated or unsaturated hydrocarbon chain such as —(CH₂)₂—, —(CH₂)₃—, —(CH₂)₄—, —(CH₂)CH(CH₃)CH₂—, —CH₂CH═CHCH₂—, —(CH₂)₅—, —(CH₂)C(CH₃)₂CH₂—, —(CH₂)₆—, —(CH₂)₂C(CH₃)₂CH₂—, —(CH₂)₂CH(CH₃)(CH₂)₂—, —(CH₂)₂CH═CH(CH₂)₂—, —(CH₂)₇—, —(CH₂)₂C(CH₃)₂(CH₂)₂—, —(CH₂)C(CH₂CH₃)₂CH₂—, —(CH₂)₈—, —(CH₂)₃C(CH₃)₂(CH₂)₂—, —(CH₂)C(CH₂CH₃)(CH₂CH₂CH₃)(CH₂)—, —(CH₂)₃CH═CH(CH₂)₃—, —(CH₂)₉—, —(CH₂)₃C(CH₃)₂(CH₂)₃—, —(CH₂)₂C(CH₂CH₃)₂(CH₂)₂—, —(CH₂)C(CH₂CH₂CH₃)₂(CH₂)—, —(CH₂)₁₀—, —(CH₂)₄C(CH₃)₂(CH₂)₃—, —(CH₂)₂C(CH₂CH₃)₂(CH₂)₃—, —(CH₂)₂C(CH₂CH₃)(CH₂CH₂CH₃)(CH₂)₂—, and —(CH₂)C(CH₂CH₂CH₃)(CH₂CH₂CH₂CH₃)(CH₂)—); a straight or branched hydrocarbon chain in which one or more methylene group, which are not adjacent, is substituted by —O—, —S—, —CO—, —CO—O— and —O—CO—, such as —CH₂OCH₂—, —(CH₂)₂OCH₂—, —(CH₂)₂O(CH₂)₂—, —(CH₂)₃O(CH₂)₂—, —(CH₂)₃O(CH₂)₃—, —(CH₂)₄O(CH₂)₃—, —(CH₂)₄O(CH₂)₄—, —CH₂SCH₂—, —(CH₂)₂SCH₂—, —(CH₂)₂S(CH₂)₂—, —(CH₂)₃S(CH₂)₂—, —(CH₂)₃S(CH₂)₃—, —(CH₂)₄S(CH₂)₃—, —(CH₂)₄S(CH₂)₄—, —CH₂COCH₂—, —(CH₂)₂COCH₂—, —(CH₂)₂CO(CH₂)₂—, —(CH₂)₃CO(CH₂)₂—, —(CH₂)₃CO(CH₂)₃—, —(CH₂)₄CO(CH₂)₃—, —(CH₂)₄CO(CH₂)₄—, —CH₂COOCH₂—, —(CH₂)₂COOCH₂—, —CH₂COO(CH₂)₂—, —(CH₂)₂COO(CH₂)₂—, —CH₂COO(CH₂)₃—, —(CH₂)₃COO(CH₂)₂—, —CH₂COO(CH₂)₄—, —(CH₂)₃COO(CH₂)₃—, —CH₂COO(CH₂)₅—, —(CH₂)₄COO(CH₂)₃—, —CH₂COO(CH₂)₇—, —(CH₂)₄COO(CH₂)₄—, and —CH₂COO(CH₂)₈—.

Furthermore, the chemical bonding chain X including a cyclic compound may be of a cyclic hydrocarbon chain only, or may be a combination of the aforementioned straight or branched hydrocarbon chain and a cyclic hydrocarbon chain. The cyclic hydrocarbon chain may be of a cycloaliphatic compound, or may be of an aromatic compound. In view of stability for an orientation of EM molecule and CTM molecule, it is preferable to include a cycloaliphatic compound. Examples of basic bone structure of the cycloaliphatic compound preferably included in the chemical bonding chain X are shown by the following formula

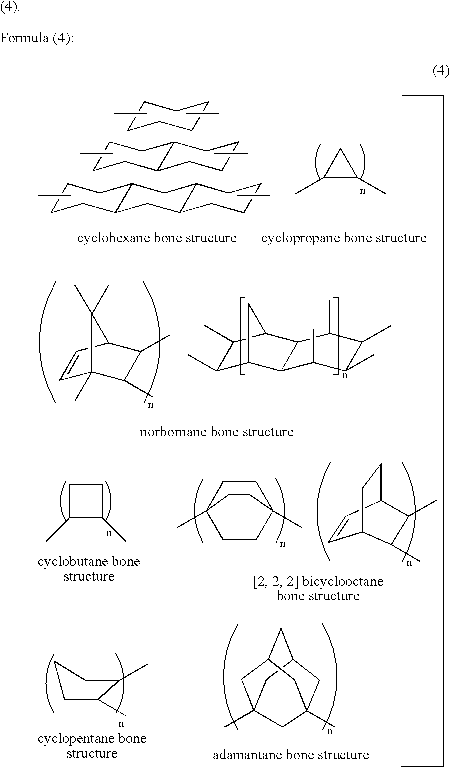

The chemical bonding chain X of the present invention is preferably electrically neutral, and preferably has a rigid bone structure as shown by the formula (4), including a cyclopropane structure, a cyclobutane structure, a cyclopentan structure, a cyclohexane structure, a norbornane structure, [2,2,2]bicyclooctane structure, [3,2,1]bicyclooctane structure, an adamantane structure and so on. A unit number as shown by formula (4) is preferably in the order of 1 to 3, depending on the bone structure to be employed in many cases.

The chemical bonding chain X including a cyclic compound is shown by the following formulae, for example. In these formulae, EM and CTM are shown to clarify an example of the bonding position.

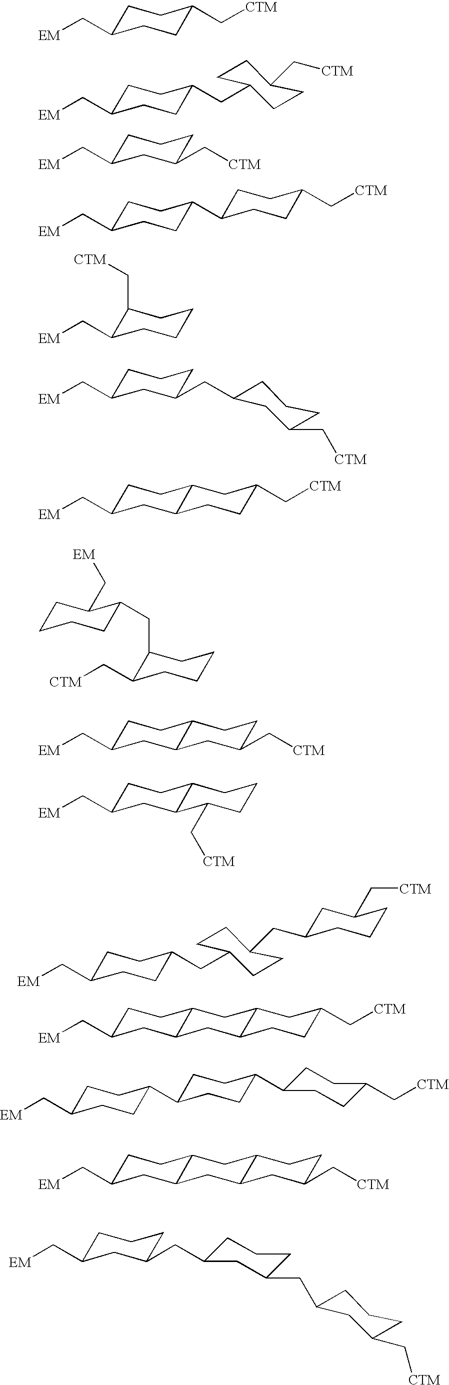

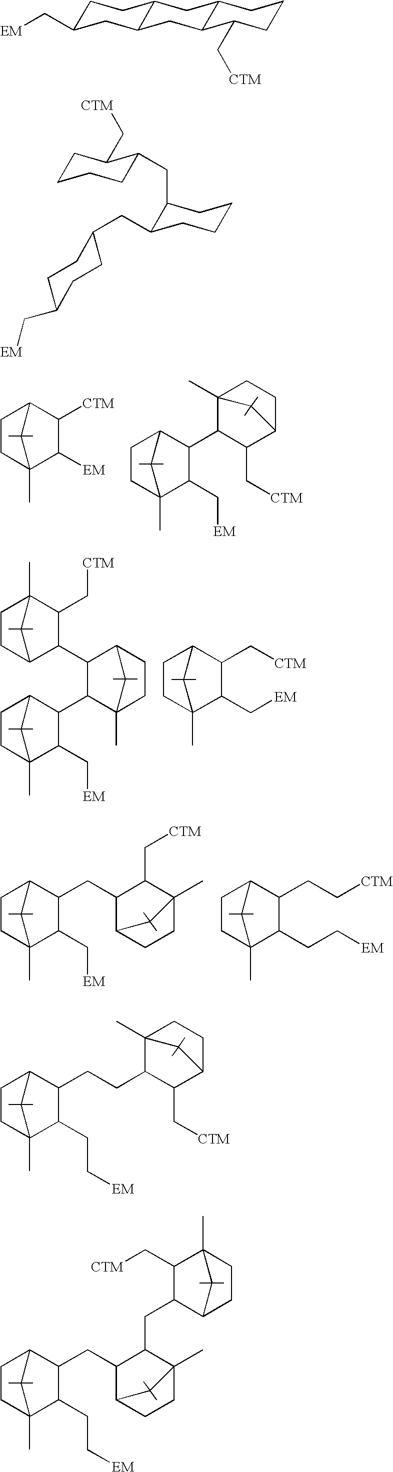

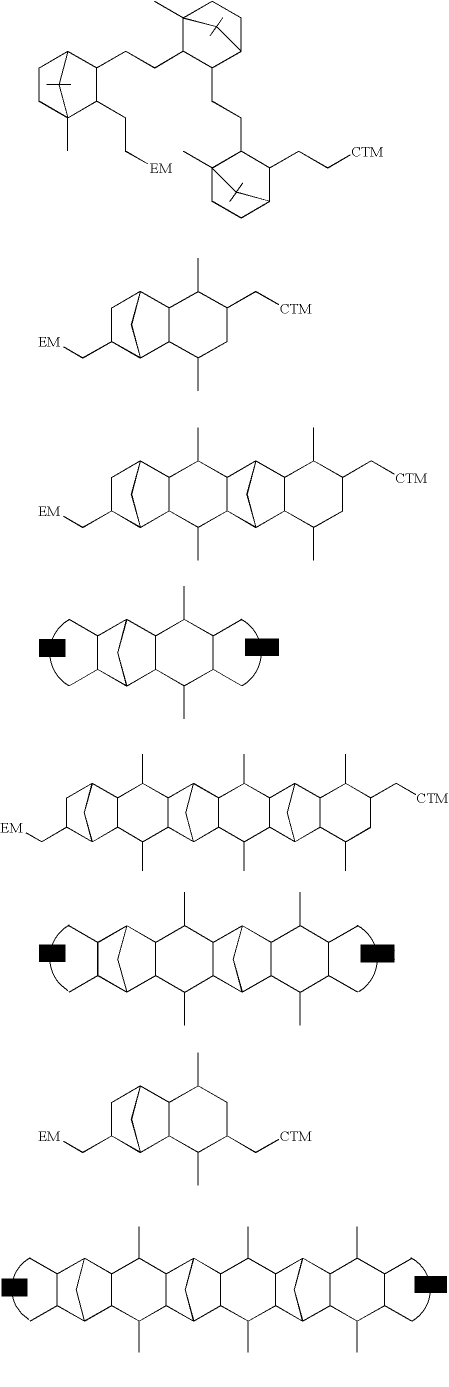

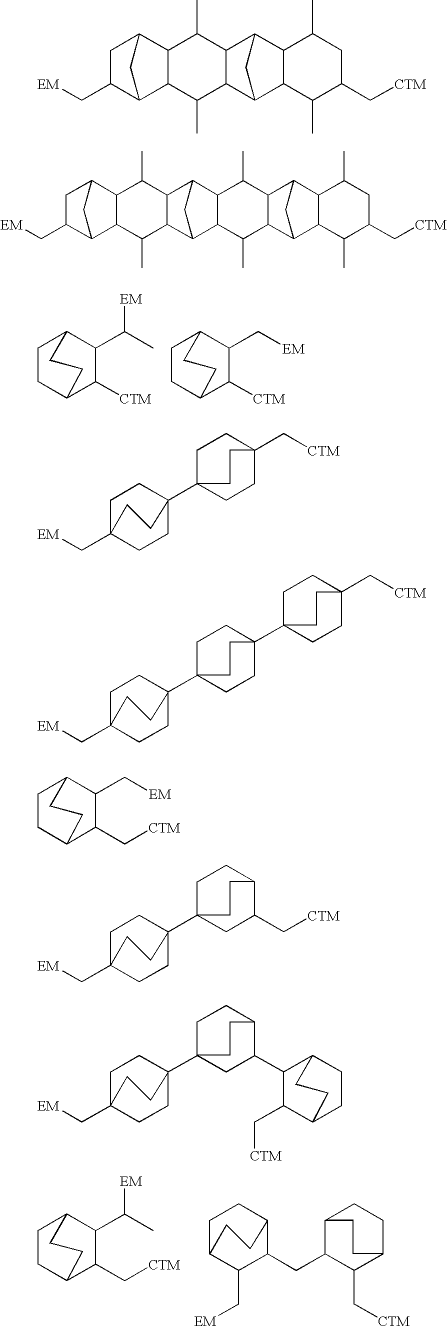

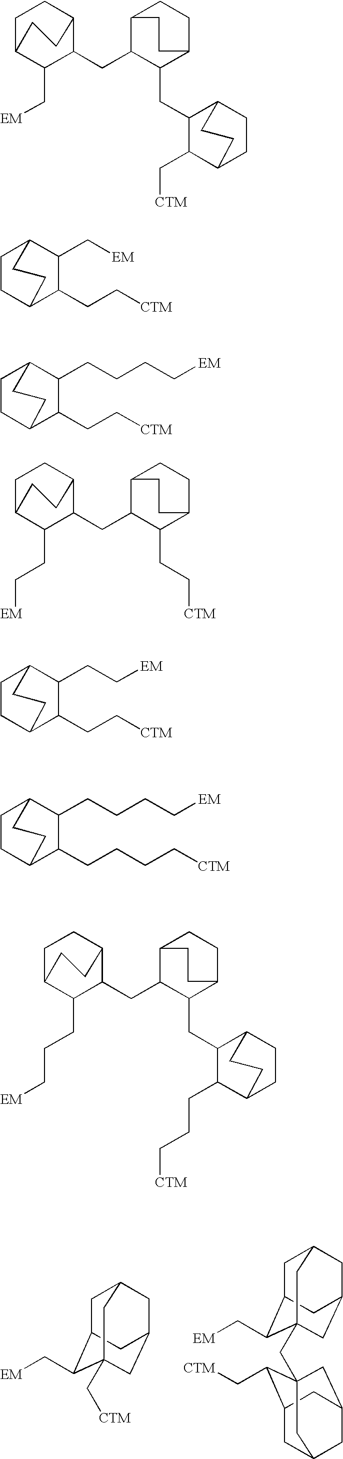

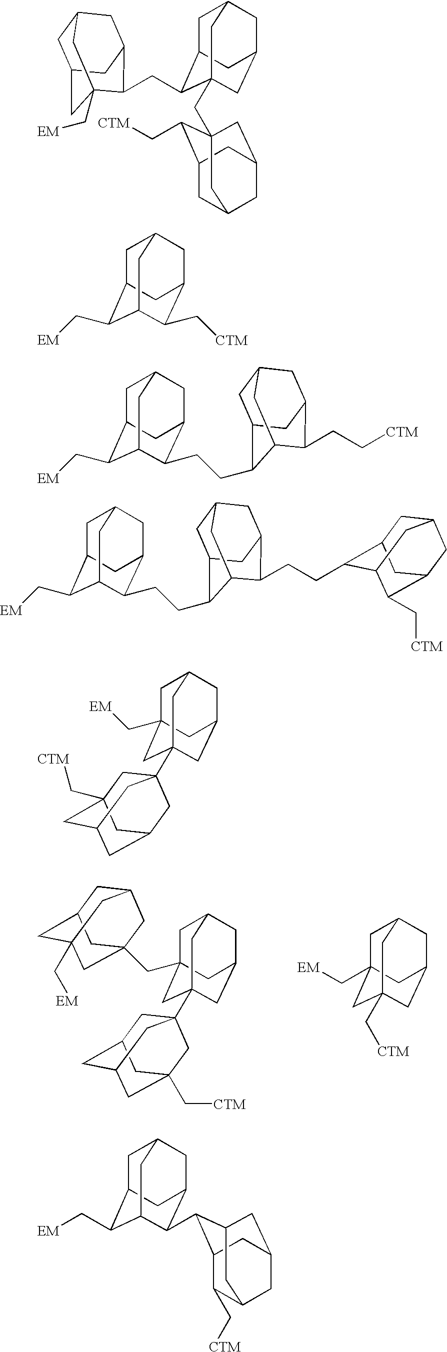

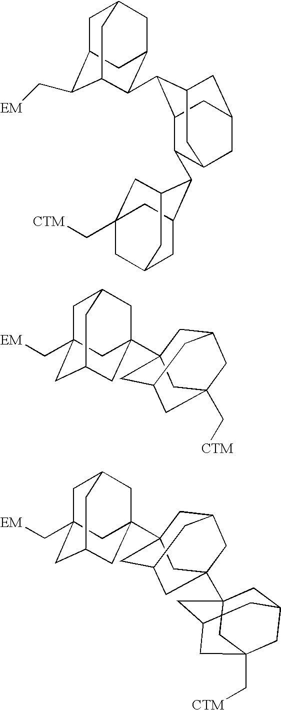

The chemical bonding chain X has a function for defining an orientation and an intermolecular distance between EM and CTM. Due to its structure and length, the chemical bonding chain X can maintain hopping conduction and/or solubility of the obtained compound. It is preferable to set (control) the chemical bonding chain X at a predetermined length. The predetermined length is set (controlled) at a distance preferably about 0.1 to 20 nm, more preferably 0.5 to 10 nm, within which a molecular orbital of a light emitting material EM and a molecular orbital of a charge transporting material CTM do not overlap. If the length of the chemical bonding chain X is too short, the molecular orbitals overlap, so that EM and CTM can not take the optimum orientation to each other due to the intermolecular rebound between EM and CTM, which tends to cause a negative influence of inhibiting a suitable energy transfer. On the other hand, if the length of the chemical bonding chain X is too long, there is a risk of deteriorating the charge transporting property between molecules, although the solubility to a solvent improves.

More specifically, taking account of the above considerations and focusing on the solubility of the obtained compound, AˆB is preferably 3 Å or more, more preferably 4 Å or more, particularly 5 Å to 50 Å, in which an atom in EM bonded to X is referred to as an atom A, an atom in CTM bonded to X is referred to as an atom B, and a shortest distance sum of interatomic distances from the atom A to the atom B via a neighboring atom on X is referred to as AˆB.

Furthermore, focusing on the hopping conduction of the obtained compound, A−B is preferably 2 Å to 50 Å, more preferably 3 Å to 30 Å, particularly 4 Å to 20 Å, wherein an atom in EM bonded to X is referred to as an atom A, an atom in CTM bonded to X is referred to as an atom B, and a linear distance between the atom A and the atom B is referred to as A−B.

In addition, the intermolecular distance and the linear distance is calculated on the basis of a structure obtained by an optimization of a compound structure, using a calculation software CAChe Worksystem Ver. 5.0 (Fujitsu), in a molecular mechanics method, MM3 (“CRC Handbook of Chemistry and Physics,” 60th Edition, R. C. Weast, (Ed.), CRC Press, Boca Raton, Fla., 1980. M. W. Chase, C. A. Davies, J. R. Downey, D. R. Frurip, R. A. McDonald, A. N. Syverud, JANAF Thermochemical Tables, Third Edition, J. Phys. Chem. Ref. Data 14, Suppl. 1 (1985). NIST Chemistry WebBook, NIST Standard Reference Database, No. 69; W. G. Mallard, P. J. Linstrom, Eds., National Institute of Standards and Technology, Gaithersberg, http://webbook.nist.gov/chemistry. J. O. Cox, G. Pilcher, “Thermochemistry of Organic and Organometallic Compounds,” Academic Press, New York, N.Y., 1970. P. v. R. Schleyer, J. E. Williams, K. R. Blanchard, J. Am. Chem. Soc., 92, 3277, (1970).).

Furthermore, in view of the solubility and the hopping conduction of the obtained compound, a ratio represented by (AˆB)/(A−B) is preferably 1.1 to 20, more preferably 1.3 to 15, particularly 1.5 to 10, wherein an EM atom bonded to X is referred to as an atom A, a CTM atom bonded to X is referred to as an atom B, a shortest distance sum of interatomic distances from the atom A to the atom B via a neighboring atom on X is referred to as AˆB, and a linear distance between the atom A and the atom B is referred to as A−B. In addition, as a value of ratio (AˆB)/(A−B) becomes larger, the conformation tends to be defined so as that a route on the chemical bonding chain X corresponding to the shortest distance sum of interatomic distances from the atom A to the atom B via a neighboring atom on X is curved to form into an arch.

In an embodiment suitable for the solubility and the hopping conduction, A−B is 2 Å to 50 Å and (AˆB)/(A−B) is 1.1 to 10, preferably A−B is 3 Å to 20 Å and (AˆB)/(A−B) is 1.2 to 9, particularly A−B is 3 Å to 15 Å and (AˆB)/(A−B) is 1.3 to 8.

In addition, the aforementioned (AˆB), (A−B), and (AˆB)/(A−B) are values determined in a case that n=1 as for the organic compound represented by the general formula (3), and values determined by using a CTM molecule most closed to EM molecule as for the organic compound represented by the general formula (1) or (2) also.

Furthermore, the chemical bonding chain X preferably has a thermally stable structure, that is, a structure uneasy to allow a free rotation and/or a structure uneasy to be cut thermally. A preferred embodiment of the chemical bonding chain X may be of a hydrocarbon chain in which any hetero atom is not included.

Particularly, the chemical bonding chain X preferably has a rigid bone structure (i.e. a bone structure thermodynamically limiting a possible stereo conformation). The rigid bonding chain X allows controlling the orientation of EM and CTM, that is, positions of molecules in the three dimensional structure. By controlling the stereo (three-dimensional) orientation of EM and CTM, there is obtained an effect that a further effective charge migration can be achieved between two molecules. Moreover, it is advantageously easy to cause the hopping conduction and to stable the effect thereof, because the rigid chemical bonding chain X becomes a barrier against the charge migration. In view of such points, a preferable embodiment of the chemical bonding chain X may be a chain containing a cycloaliphatic compound, and may be of containing a chemical bonding chain represented by the formula (4).

Orientation of the EM and CTM in the organic compound of the present invention is preferably controlled at a predetermined orientation at which the hopping conduction can be maintained. In thermodynamically stable conformation, the orientation of the EM and CTM is preferably an orientation at which a straight line, extending from a center of an EM molecule to a center of a conjugated surface of a CTM molecule, intersects with the conjugated surface of the CTM molecule at approximately right angle. In addition, the thermodynamically stable conformation can be obtained by the optimization of the structure, similarly to the method for obtaining the aforementioned linear distance A−B.

The substituent Y is a substituent introduced at any part of EM, CTM or X for improving at least solubility to a solvent. Although the chemical bonding chain X also has the solubility to a solvent, there is a need to elongate the chemical bonding chain X in order to further improve the solubility to a solvent, which may reduce the rigidity suitable for the chemical bonding chain X and easily reduces the charge transporting property. Therefore, it is preferable that the substituent Y is added to compensate the solubility to a solvent to present a chemical structure having a good charge transporting property.

This substituent Y is selected from a group consisting of hydrogen atom, alkyl group having 1 to 20 carbon atoms, alkoxy group having 1 to 20 carbon atoms, alkylthio group having 1 to 20 carbon atoms, alkylsilyl group having 1 to 60 carbon atoms, alkylamino group having 1 to 40 carbon atoms, aryl group having 6 to 60 carbon atoms, arylalkyl group having 7 to 60 carbon atoms, arylalkoxyl group having 7 to 60 carbon atoms, arylalkynyl group having 8 to 60 carbon atoms, arylamino group having 6 to 60 carbon atoms, heterocyclic group having 4 to 60 carbon atoms, cyano group, nitro group, and halogen atoms.

The aryl group listed above indicates preferably a substituted or non-substituted arylene group having 6 to 60 carbon atoms relating to a conjugated bond, or a substituted or non-substituted heterocyclic group having 4 to 60 carbon atoms relating to a conjugated bond. Furthermore, the alkyl group thereof is a straight or branched alkyl group, in which one or more methylene group, which are not adjacent to each other, may be substituted by —O—, —S—, —CO—, —CO—O—, —O—CO—, CH═CH—, —C≡C—, and a hydrogen atom in this alkyl group maybe substituted by a fluorine atom.

Furthermore, this substituent Y may act to give the compound with a stereo hindrance effect. By adding the substituent Y to either part of EM, CTM or X, an EM molecule and a CTM molecule are twisted around X as an axis, because the substituent Y becomes a hindrance. Such a twisted distortion changes the orientation of the EM molecule and the CTM molecule, so that a property based on the orientation can be presented.

In addition, Ar in the aforementioned formula (3) indicates a substituted or non-substituted arylene group having 6 to 60 carbon atoms relating to a conjugated bond, or a substituted or non-substituted heterocyclic group having 4 to 60 carbon atoms relating to a conjugated bond. Furthermore, each R indicates independently a function group selected from a group consisting of hydrogen atom, alkyl group having 1 to 20 carbon atoms, alkoxy group having 1 to 20 carbon atoms, alkylthio group having 1 to 20 carbon atoms, alkylsilyl group having 1 to 60 carbon atoms, alkylamino group having 1 to 40 carbon atoms, aryl group having 6 to 60 carbon atoms, arylalkyl group having 7 to 60 carbon atoms, arylalkoxy group having 7 to 60 carbon atoms, arylalkynyl group having 8 to 60 carbon atoms, arylamino group having 6 to 60 carbon atoms, heterocyclic group having 4 to 60 carbon atoms, cyano group, nitro group, and halogen atoms.

The general formula (3) indicates an exemplary generalized structure of the organic compound structure. In the general formula (3), M is selected from transition metals including ruthenium, osmium, rhodium, iridium, palladium, platinum and so on; 1 is an integer from 0 to 2, m is an integer from 1 to 3, n is an integer from 1 to 3. In this case, the sum of 1 and m is 2 or 3. Furthermore, A to D may be the same as indicated by the general formula (3).

The following formulae (5) to (9) are examples of the aforementioned general formula (3). As shown herein, a compound to form an organic compound layer may take various embodiments based on (EM-X—CTM)-Y.

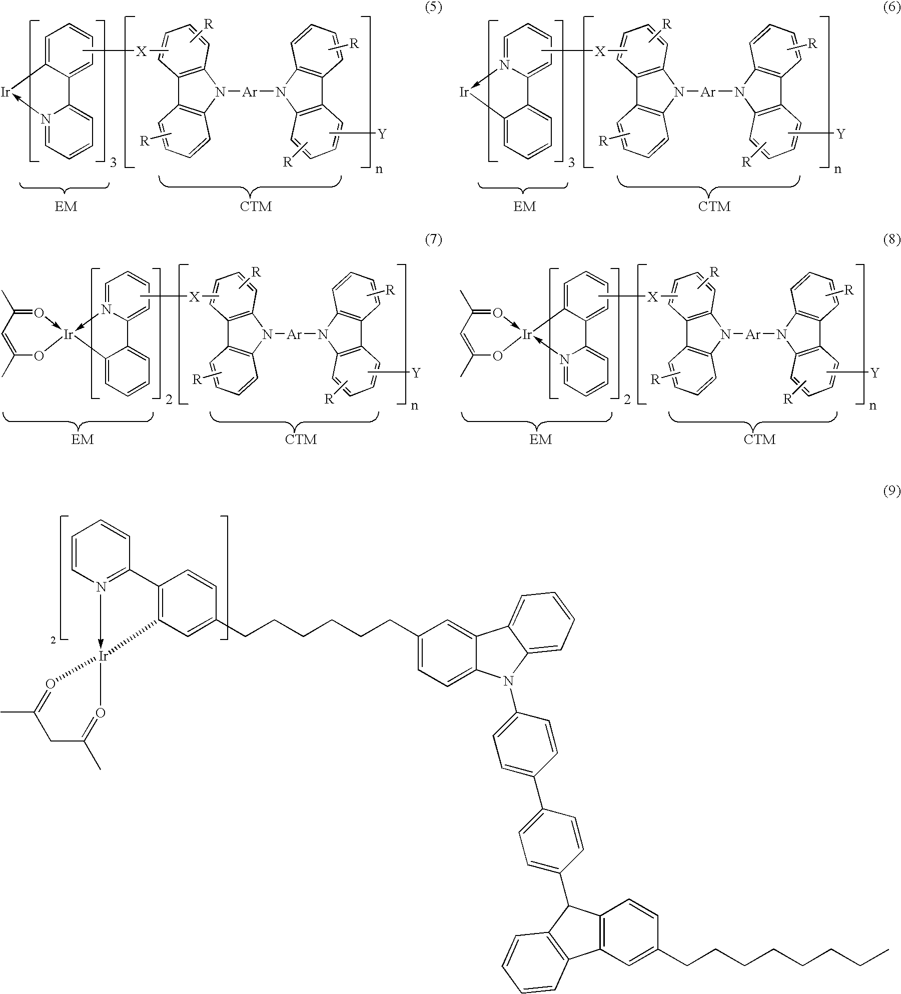

As mentioned above, it is possible to improve the easiness in coating and uniform dispersibility within a layer (film) by adding a solvent-soluble molecular chain into the compound. Owing to the fact that the compound disperses uniformly within the layer, a deterioration due to the intermolecular interaction can be restrained and an element life can be elongated. Furthermore, Due to the fact that an intermolecular distance between a host and a guest, which are most closely adjacent to each other and bonded to each other by the added molecular chain, is optimized, the luminous efficiency on recombination can be remarkably improved, in comparison with a phosphorescent element involving the conventional coating process.

Furthermore, a bonding unit to be used, and the repeating unit number thereof or the total atom number can be controlled in the aforementioned compound, so that the intermolecular distance between the light emitting material EM and the charge transporting material CTM can be optimized. Furthermore, the relative orientation of the host-guest unit can be freely determined by suitably changing the bonding position or the kind of the chemical bonding chain X. In a case that a compound having both these host-guest units is used as a guest, and a solution mixture thereof with a high or low molecular host material is coated, there is an effect that differences of the packing density and orientation between the deposition film and the coating layer of the same composition can be overcome.

With regard to the luminous efficiency, it is important how efficient the energy transfer between a host and a host (host-host), or between a host and a guest (host-guest) is. In addition to this, the organic compound of the present invention has a further effect that the orientation of EM and CTM is optimized by the chemical bonding chain X, and thereby the charge migration between EM and CTM is stabilized, as well as the compound is dispersed uniformly within the layer. Therefore, the organic compound of the present invention can be used suitably as an organic EL element material or organic EL element luminescence material, so that efficient and stable light emission can be achieved with the organic EL element, and thereby the life of the organic EL element can be elongated.

<Organic EL Element>

Hereinafter, a detail explanation will be made on the organic EL element of the present invention.

The organic EL element is provided with: at least a pair of opposite electrodes; and one or more organic compound layers sandwiched between the pair of opposite electrodes, characterized in that at least one layer of the organic compound layers contains the organic compound of the present invention as mentioned above.

Now, a typical layered structure of the organic EL element of the present invention and the fabrication method thereof will be explained.

(Substrate)

A substrate is disposed usually on a surface at an observer's side. Thereby, this substrate preferably has an extent of transparency allowing the observer to easily view light from the light emitting layer. Incidentally, if an opposite side of the substrate is the observer's side, this substrate may be opaque.

The substrate may be a film-like resin substrate or may be a glass substrate covered with a protective plastic film or protective plastic layer.

The resin material or the protective plastic material to form the substrate may be: a fluorine resin; polyethylene; polypropylene; polyvinyl chloride; polyvinyl fluoride; polystyrene; an ABS resin; polyamide; polyacetal; polyester; polycarbonate; modified polyphenylene ether; polysulfone; polyalylate; polyetherimide; polyamideimide; polyimide; polyphenylene sulfide; liquid crystalline polyester; polyethylene terephthalate; polybutylene terephthalate; polyethylene naphthalate; polyoxymethylene; polyether sulfone; polyetheretherketone; polyacrylate; an acrylonitrile-styrene resin; a phenol resin; an urea resin; a melamine resin; an unsaturated polyester resin; an epoxy resin; polyurethane; a silicone resin; an amorphous polyolefin and so on. Other resin materials may be used, insofar as it is a high molecular material satisfying a requirement sufficient to be used as an organic EL element. A thickness of the substrate is usually 50 to 200 μm.

In these substrates, it is more preferable to have a good gas barrier property against moisture, oxygen and soon, depending on their individual use. Incidentally, a gas barrier layer against moisture, oxygen and so on may be formed on the substrate. The barrier layer may be formed by a physical vapor deposition process such as a spattering process or a vacuum deposition process from an inorganic oxide such as silicon oxide, aluminum oxide, titanium oxide and the like.

(Electrode)

Electrodes are disposed either side of the organic compound layer so as to sandwich the organic compound layer. An electrode at a substrate side may be an anode (positive electrode) or may be a cathode (negative electrode). In this application, an explanation will be made considering this electrode as anode. The electrode at the substrate side is disposed on the substrate in such a manner that it abuts on the light emitting layer in order to inject positive electric charge (positive hole) Incidentally, in the case that a hole transporting layer is disposed between the light emitting layer and the substrate, this electrode is disposed adjacent to the hole transporting layer.

The electrode as anode is not limited to any special electrode insofar as it can be used for a usual organic EL element, but may be: a conductive metal oxide such as tin oxide, zinc oxide, indium oxide, indium tin oxide (ITO) and so on; a metal such as gold, silver, chrome, nickel and so on; a conductive organic material such as polyaniline, polythiophene, polypyrrole and so on; a mixture thereof or layered structure thereof; and so on. From among them, ITO, indium oxide, gold and IZO are preferable, which are transparent or semi-transparent material whose work function is large, in order to facilitate the injection of positive holes. A thickness of the electrode is preferably 0.005 to 0.5 μm in any case, and the electrode is usually formed as a pattern or over an entire surface of the substrate by the spattering process or the vacuum deposition process. The pattern-like electrode is formed by an etching process using a photoresist, after forming the electrode over the entire surface.

On the other hand, another electrode to be disposed opposite to the aforementioned electrode should have a polarity different from that of the aforementioned electrode. In this application, an explanation will be made considering another electrode as cathode. This electrode (hereinafter referred to as “cathode”) is disposed in such a manner that it abuts on the electron injecting layer in order to inject negative electric charge (electron) into the light emitting layer.

The cathode is not limited to any special electrode insofar as it can be used for a usual organic EL element, but may be: a thin film electrode material, similarly to the aforementioned electrode (anode), such as indium tin oxide (ITO), indium oxide, indium zinc oxide (IZO), gold or the like, and additionally may be a magnesium alloy (MgAg etc.); aluminum or alloy thereof (AlLi, AlCa, AlMg, etc.); silver and so on. From among, it is preferable to use a material, whose work function is small less than 4 eV in order to facilitate the injection of electrons, such as an alkali metal (e.g. lithium, sodium, cesium, etc.) and halide thereof (e.g. lithium fluoride, sodium fluoride, cesium fluoride, lithium chloride, sodium chloride, cesium chloride, etc.); an alkaline earth metal (calcium, magnesium, etc.) and halide thereof (e.g. calcium fluoride, magnesium fluoride, calcium chloride, magnesium chloride, etc.); a metal such as aluminum, silver and so on; a conductive metal oxide and alloy or mixture thereof, and so on. A thickness of the cathode is preferably 0.005 to 0.5 μm in any case, and the electrode is usually formed by a vacuum deposition process, a spattering process, a laminating process of pressure-bonding a metal thin film, and so on.

Incidentally, after the cathode is fabricated, a protective layer may be attached in order to protect the organic EL element. In order to use the organic EL element stably for a long time, it is preferable to attach the protective layer or protective cover for protecting the element from an external environment. The protective layer may be of a high molecular compound, a metal oxide, a metal fluoride, a metal boride, silicon oxide, silicon nitride and so on. Furthermore, the protective cover may be of a glass plate, or a plastic plate whose surface is treated to reduce coefficient of water permeability, and a method to bond and seal this cover to a substrate of the element with thermosetting resin or photocurable resin is preferably adapted.

(Organic Compound Layer)

One or more organic compound layer sandwiched between electrodes, namely the organic EL layer, is referred to a layer for causing an electroluminescence, in a broad meaning, including not only the light emitting layer but also an embodiment of multi-layered structure made of an optional combination of a positive hole transporting layer for transporting a positive hole to the light emitting layer, a positive hole injecting layer for injecting a positive hole into the positive transporting layer and the light emitting layer, an electron transporting layer for transporting an electron into the light emitting layer, an electron injecting layer for injecting an electron into the electron transporting layer and the light emitting layer, and other layers.

Specifically, there are included an embodiment in which a layered structure of “positive hole transporting layer/light emitting layer/electron injecting layer” is formed in this order, an embodiment in which a layered structure of “light emitting layer/electron transporting layer/electron injecting layer” is formed in this order, and so on. Furthermore, in a case that a positive hole transporting material and/or an electron transporting material are added to the light emitting layer, the positive hole transporting layer and/or the electron transporting layer may be omitted. Incidentally, an insulation layer made of a material including a photocurable resin, such as a UV curable resin, or a thermosetting resin may be formed partially or wholly between this organic EL element and the electrodes, in order to prevent a defect such as a short circuit from being arisen. Furthermore, a light shielding layer such as a black matrix may be disposed.

(Light Emitting Layer)

The light emitting layer is an indispensable layer for the organic EL element, and made of a material containing the organic compound of the present invention. The organic compound of the present invention has been discussed above, and therefore the explanation thereof is omitted hereinafter.

The material for the light emitting layer preferably contains not only the organic compound of the present invention but also a charge transporting material. The charge transporting material may be a conventional low molecular material for a positive hole transporting material, an electron transporting material, a hole electron transporting material, or may be a high molecular material, for example. The positive hole transporting material may be an aromatic tertiary amine derivative, starburst polyamines, and a phthalocyanine metallic complex derivative. The charge transporting material may be an Alq₃ derivative, an oxadiazole derivative, a triazole derivative, an imidazole derivative, a triazine derivative and a phenylquinoxalline derivative. The hole charge transporting material may be a carbazole biphenyl (CBP).

The high molecular material may be a poly-p-phenylene-vinylene derivative, a polythiophene derivative, a poly-p-phenylene derivative, a polysilane derivative, a polyacetylene derivative and the like, a polyfluorene derivative, a polyvinyl carbazole derivative, the colorants listed above, and a polymerized product of metallic complex light emitting material, for example.

Furthermore, other light emitting material different from the organic compound of the present invention mentioned above may be included in the material for the light emitting layer. The other light emitting material may be a fluorescent light emitting material and phosphorescent light emitting material, which are conventionally used. Such a fluorescent light emitting material may be a colorant material and a metallic complex material. Such a colorant material maybe for example: a polycyclic aromatic hydrocarbon such as a coumarin derivative, a DCM2 (quinolidine derivative), a quinacrydone derivative, perylene, rubrene and the like; a pyrene derivative; a pyrrolopyrrole derivative; a styrylbenzene derivative, a polymethine derivative and a xanthene derivative. Such a metallic complex material may be for example: a quinolinol complex derivative such as Alq₃ (alminoquinolinol complex); a quinoline complex derivative such as Beq₂ (beryllium-quinoline complex); a hydroxyphenyl oxazole or a hydroxyphenyl thiazole; and an azomethine metallic complex derivative. Such a phosphorescence light emitting material may be for example a transition metal complex including: an iridium complex derivative such as Ir(ppy)₃; and a platinum complex derivative such as PtOEP.

Furthermore, for a purpose of improving the luminous efficiency or changing a luminous wavelength, a doping may be performed relative to the light emitting layer. Such a doping material may be for example a perylene derivative, a coumarin derivative, a quinacridon derivative, a squalium derivative, a polyphyrin derivative, a styryl dye, a tetracene derivative, a pyrazolline derivative, decacyclene and phenoxazone.

The light emitting layer, which is a layer comprising the organic compound of the present invention on the electrode and preferably further comprising the charge transporting material as a host material, and still further, if needed, comprising the light emitting material and the doping material, is formed for example by coating a solution mixture containing the organic compound of the present invention and the charge transporting material as a high molecular or low molecular host material, and further containing, if needed, the light emitting material, the doping material, and other components such as a dispersant, a surfactant, and so on. The solvent may be an aromatic solvent such as toluene or xylene, a halogenated hydrocarbon solvent such as chloroform or 1,2-dichloroethane, an ether solvent such as tetrahydrofuran. The solution mixture preferably contains: the organic compound of the present invention at 0.01 to 10% by weight, more preferably 0.01 to 5% by weight; the charge transporting material as the host material at 0 to 20% by weight, more preferably 0 to 10% by weight; if needed, the light emitting material at 0.1 to 10.0% by weight, the doping material at 0.01 to 5.0% by weight, other components at 0.1 to 5% by weight in total; and the solvent at 50 to 99.99% by weight.

The light emitting layer can be formed from this solution mixture by a coating process including spin coating, cast coating, dip coating, die coating, bead coating, bar coating, roll coating, spray coating, gravure coating, flexoprinting, screenprinting, offset printing or the like. A film thickness of the light emitting layer is 1 nm to 1 μm, preferably 2 nm to 500 nm, more preferably 5 nm to 500 nm. Incidentally, in a case that the film is formed by a coating process, it is preferable to dry the film at 30 to 300° C., preferably 60 to 200° C., preferably under reduced pressure or under inert atmosphere, in order to eliminate the solvent.

Furthermore, in a case that another charge transporting material layer is stacked on the light emitting layer, it is preferable to form the positive transporting layer on the anode, before the light emitting layer is formed by the aforementioned process, or form the electron transporting layer, after the light emitting layer is formed.

(Positive Hole Transporting Layer)

The positive hole transporting layer is disposed between the anode and the light emitting layer, or between the positive hole injecting layer and the light emitting layer. The positive hole transporting material to form the positive hole transporting layer may be for example: a heterocyclic compound represented by triphenylamines, bis's, pyrazoline derivatives and polyphyrin derivatives; polymers such as polycarbonate, styrene derivatives, polyvinyl carbazoles, and polysilanes, which have respectively the aforementioned monomer as a side chain. The positive transporting layer may be formed by a deposition process, a spattering process, a printing process and so on. A film thickness of the positive hole transporting layer is preferably in the order of 1 nm to 1 μm.

(Positive Hole Injecting Layer)

The positive hole injecting layer can be disposed between the anode and the positive hole transporting layer, or between the anode and the light emitting layer. The material to form the positive hole injecting layer may be a phenylamine, a starburst type amine, a phthalocyanine, an oxide such as vanadium oxide, molybdenum oxide, ruthenium oxide, aluminum oxide and the like, an amorphous carbon, a polyaniline, a polythiophene derivative and so on.

A process or method of forming the positive hole injecting layer is not limited to any special process or method, but may be: a vacuum deposition process or method from a solid state; or a spin coating, cast coating, dip coating, die coating, bead coating, bar coating, roll coating, spray coating, gravure coating, flexo printing, screen printing, offset printing from a molten state, a solution state, a dispersion liquid, or a solution mixture state. A film thickness of the positive hole injecting layer is 1 nm to 1 μm, preferably 2 nm to 500 nm, more preferably 5 nm to 200 nm.

(Electron Transporting Layer)

The electron transporting layer can be disposed between the light emitting layer and the cathode, or between the light emitting layer and the electron injecting layer. The material to form the electron transporting layer may be for example a material having a high ionization potential and typically generating a stable radical anion, such as oxadiazoles, alminumquinolinol complex, and so on. Specifically, there may be listed 1,3,4-oxadiazole derivatives, 1,2,4-triazole derivatives, imidazole derivatives and so on. The electron transporting layer may be formed by a deposition process, a spattering process, a printing process and so on. A film thickness of the electron transporting layer is preferably in the order of 1 nm to 1 μm.

(Electron Injecting Layer)

The electron injecting layer can be disposed between the electron transporting layer and the cathode, or between the light emitting layer and the cathode. As the electron injecting layer, it is possible to dispose an electron injection layer, depending on a kind of the light emitting layer, comprising a single layered structure of Ca layer, or comprising a multi-layered structure of the Ca layer and another layer made of one or more kinds selected from the group consisting of: a metal and the oxide, halide and carbonate of such a metal, of IA group and IIA group (excluding Ca) of the periodic system, and which has 1.5 to 3.0 eV work function. Examples of the IA group metal having 1.5 to 3.0 eV work function, or oxide, halide and carbonate thereof are lithium, lithium fluoride, sodium oxide, lithium oxide, lithium carbonate and so on. Furthermore, examples of the IIA group metal (excluding Ca) having 1.5 to 3.0 eV, or oxide, halide and carbonate thereof are strontium, magnesium oxide, magnesium fluoride, strontium fluoride, barium fluoride, strontium oxide, magnesium carbonate and so on. The electron injecting layer may be formed by a deposition process, a spattering process, a printing process and so on. A film thickness of the electron injecting layer is preferably in the order of 1 nm to 1 μm.

Thus, the organic EL element of the present invention has been discussed about its structure. Nevertheless, other functional layers different from the discussed layers may be disposed, insofar as it is within a range of the object and effect of the present invention. Such a functional layer may be: a low refraction index layer; a reflection layer; a light absorption layer; a barrier layer; a sealant layer and so on, which are used for a usual organic EL element or light emitting display device, respectively. Furthermore, the functional layer may include a diaphragm.

In order to obtain a planar organic EL element, it is possible to dispose a planar anode and a planar cathode in such a manner that they overlap with each other. Furthermore, in order to obtain a pattern-like light emission, there may be used: a method of disposing a mask having a pattern-like window on a surface of the planar light emitting element; a method of forming an extremely thick organic layer at non-light emitting part and thereby substantially preventing the light emission; and a method of forming either anode or cathode, or both, in one or more pattern. Furthermore, in order to obtain a dot matrix element, there may be used: a method of forming stripe-shaped anode and cathode and disposing them in such a manner that they intersects at right angle each other; a method of selecting and driving one of electrodes with a TFT; and so on. Furthermore, it is possible to achieve a partial color display, a multiple color display, a full color display by disposing a plurality of organic EL elements of different colors to be emitted on the same surface.

### EXAMPLES

The present invention will now be explained further in detail with reference to the examples and comparative examples.

### Example 1

### Synthesis of Organic Compound 1 of the Present Invention

Now, there is shown an example of a method for synthesizing a compound represented by the aforementioned general formula (2) (hereinafter this compound is referred to as “the compound (2)”, as appropriate). In this example 1, in the compound (2), EM is an iridium coordination compound, X is —(CH₂)₆—, CTM is CBP (4,4′-bis(carbazol-9-yl)-biphenyl), Y is —(CH₂)₇CH₃. As the reagent, the following is used without refining, including: calcium chloride, anhydrous magnesium sulfate, sodium carbonate, potassium carbonate, sodium hydroxide, which are purchased from JUNSEI CHEMICAL; anhydrous aluminum chloride, anhydrous 1,2-dichloroethane, n-butyl-lithium, 2-isopropoxy-4,4,5,5-tetramethyl-1,3,2-dioxabororan, Pd(PPh₃)₄, triethyl phosphite, which are purchased from ALDRICH; iridium chloride (III) trihydrate, which is purchased from Acros Organics; anhydrous ethanol, anhydrous toluene, anhydrous DMF, anhydrous chloroform, chloroform, anhydrous THF, ethanol, toluene, dichloromethane, chloroform, ethyl acetate, anhydrous methanol, methanol, diethyl ether, diethylene glycol, distilled water, sodium borohydride, sodium hydride, 2-ethoxy-ethanol, hydrazine hydrate, 2-bromo-pyridine, sodium, hydrochloric acid, thionyl chloride, sodium borohydride, which are purchased from KANTO CHEMICAL CO., INC.; and n-octylic acid chloride, 4-bromo-benzaldehyde, 10%-Pd/C catalyst, 4-bromobutyl-acetal, whichare purchased from TOKYO KASEI KOGYO CO., LTD.

As CBP, a product obtained by heating 4,4′-diiodebiphenyl and carbazole, in presence of cupper powder and potassium carbonate, up to 200° C. in diisopropylbenzene, with a nitrogen gas stream (ref. B. E. Koene, et al., Chem. Mater. 10(8), 1998, 2235-2250.) is used.

1. Synthesis of Ligand

### Synthesis of Alkyl CBP [1]

A reacting solution is prepared, by putting 2.7 g (20 mmol) of anhydrous aluminum chloride, 30 mL of anhydrous 1,2-dichloroethane, and 8.7 g (18 mmol) of CBP, into a three-necked 100 mL flask substituted by argon after dried by heat under reduced pressure. While stirring the reacting solution with ice-cooling in order to maintain the solution at 20° C., 5.7 g (35 mol: 6.0 mL) of n-octylic acid chloride is dropped into the reacting solution. After the dropping, the reacting solution is stirred for an hour, and then left for 12 hours at a room temperature. Then, the reacting solution is poured onto 20 g of ice, so that an organic phase is separated and a water phase is extracted with dichloromethane (20 mL×2). The separated organic phase is collected and then washed by 2% sodium hydroxide aqueous solution, water, and saturated sodium chloride aqueous solution. Then, the washed organic phase is dried with anhydrous magnesium sulfate, and then concentrated under reduced pressure, so that a crude product is obtained. The crude product is subjected to flash column chromatography (hexane:ethyl acetate=10:1), so that 7.2 g (12 mmol: 67%) of a ketone [1] represented by the following formula is obtained.

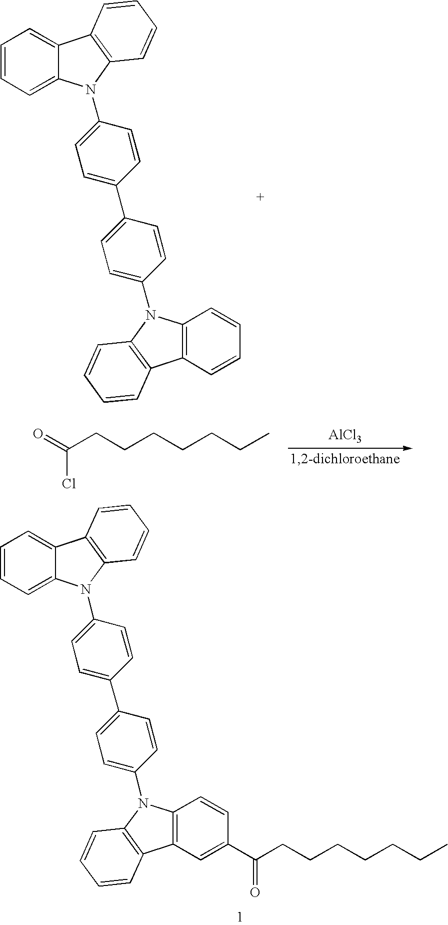

Then, 6 g (9.8 mmol) of the obtained compound [1] is put into a 100 mL recovery flask (egg plant shaped flask) and then 1.8 mL (27 mmol) of 80% hydrazine hydrate, 1.8 g of sodiumhydroxide, 22 mL of diethylene glycol are mixed to conduct a heating reflux for 2 hours. Then, a heating reflux device is substituted by a distillation head, and the inner temperature is gradually raised to 195 to 200° C. After achieved that temperature, the resultant is maintained at that temperature for 6 hours, so that a mixture of hydrazine and H₂O is distillated. The mixture is cooled and then diluted with 35 mL of water and then extracted with toluene (100 mL×3). The collected organic phase is washed by water and saturated sodium chloride aqueous solution, and then dried with anhydrous magnesium sulfate, and then concentrated under reduced pressure, so that a crude product is obtained. The crude product is subjected to flash column chromatography (hexane: ethyl acetate=15:1), so that 4.7 g (7.6 mmol: 80%) of a desired compound [2] represented by the following formula is obtained.

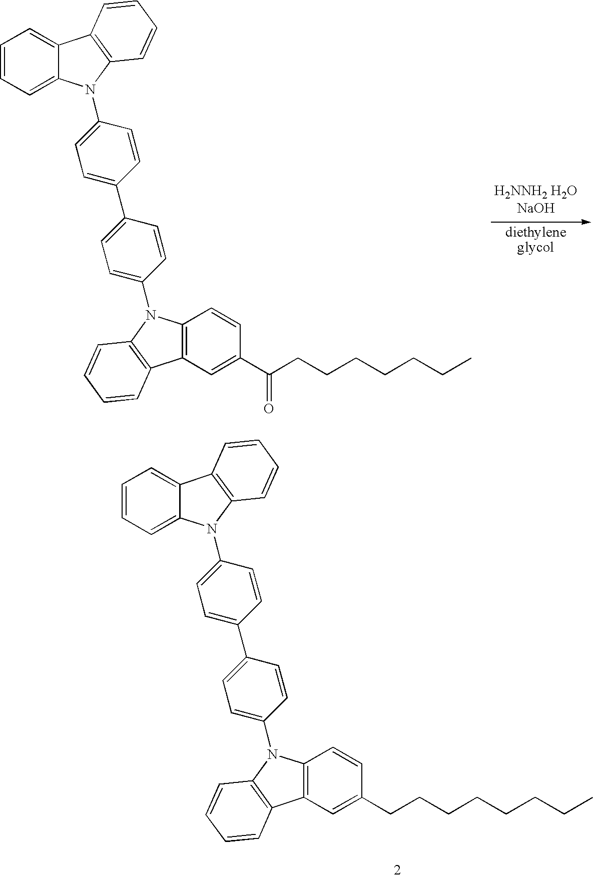

### Synthesis of Acid Chloride [9]

First of all, phenyl pyridine formate [4] is synthesized. 5.5 mL (24.7 mmol) of 4-bromo-benzaldehyde is dissolved into 60 mL of THF, and cooled to −78° C. under nitrogen atmosphere. Then, 10 mL (25 mmol, 2.5 M) of n-butyl lithium is dropped into the solution to cause a reaction for an hour. After an hour, 2.76 g (15 mmol) of 2-isopropoxy-4,4,5,5-tetramethyl-1,3,2-dioxabororan (DOB) is added to continue the reaction for another one hour. After the reaction is completed, the resultant is backed to the room temperature and then stirred for 30 minutes, and then extracted with 300 mL of diethyl ether in three times. The collected organic phase is washed by 2% sodium hydroxide aqueous solution, water, and saturated sodium chloride aqueous solution, and then dried with anhydrous magnesium sulfate, and then concentrated under reduced pressure, so that 6.5 g of a crude product [3] represented by the following formula is obtained.

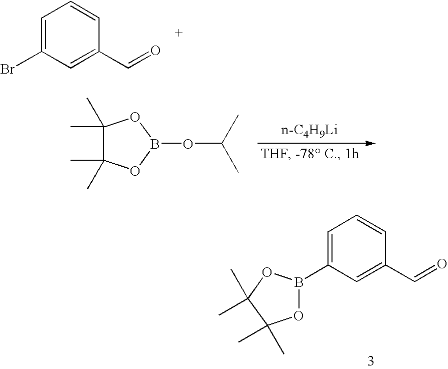

2.9 g of the obtained crude product [3], 2-bromopyrizine (14.32 mmol) and 1 mg (0.87 mmol) of Pd(PPh₃)₄ are putted into a three-necked 300 mL flask substituted by argon after dried by heat under reduced pressure, so that they are dissolved into 155 mL of anhydrous THF. 108 mL (216 mmol) of 2M-potassium carbonate aqueous solution is poured into the flask, and then stirred at 60° C. for 10 hours. Then, the flask are cooled with ice, and 200 mL of 1N hydrochloric acid is added and then extracted with diethyl ether (200 mL×3). The collected organic phase is washed by water and saturated sodium chloride aqueous solution, and then dried with anhydrous magnesium sulfate, and then concentrated under reduced pressure, so that a crude product is obtained. The crude product is subjected to flash column chromatography (hexane:ethyl acetate=10:1), so that 1.8 g (10 mmol: 70%) of phenyl pyridine formate [4] represented by the following formula is obtained.

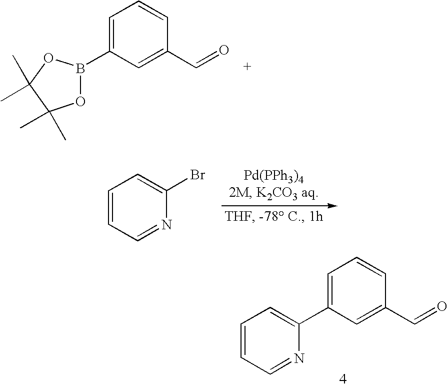

Next, phenyl pyridine alkenyl acetal [6] is synthesized. 10 mL (83 mmol) of 4-bromo butyl acetal and 18.9 g (83 mmol) of triethyl phosphite [5] are put into a 200 mL three-necked flask substituted by argon after dried by heating under reduced pressure, so that they are dissolved into 40 mL of anhydrous benzene. While stirring at a room temperature, a solution of sodium 1.8 g (83 mmol) dissolved in anhydrous methanol 40 mL is dropped into the flask. Then, 15 g (82.0 mmol) of phenyl pyridine formate [4] is poured little by little into the flask, and then the obtained yellow solution is stirred at 40° C. for 2 hours. The solution is poured onto 160 g of ice, and then extracted with diethyl ether (100 mL×3). The collected organic phase is washed by water (200 mL×2), and then dried with saturated sodium chloride aqueous solution. The solvent is distilled away under reduced pressure, and the residue is subjected to flash column chromatography (hexane:ethyl acetate=20:1), so that 19.4 g (65.6%) of desired phenyl pyridine alkenyl acetal [6] represented by the following formula is obtained.

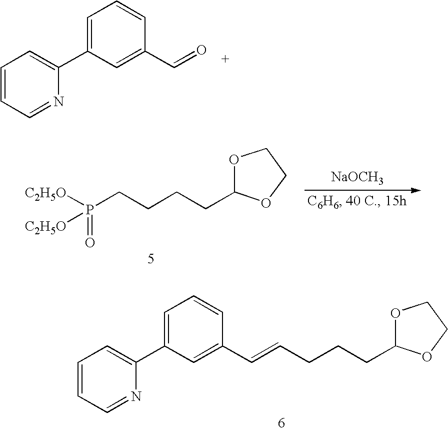

Next, phenyl pyridine alkyl acetal [7] is synthesized. A suspension is prepared by 0.50 g of 10% Pd/C catalyst is added into an ethanol (70 mL) solution of phenyl pyridine alkenyl acetal [6] 12 g (41 mmol). The suspension is subjected to a deaeration under reduced pressure and a hydrogenation, by three time for each operation, using a reduction device. Then, the suspension is stirred at a room temperature for 3 hours, under 2 atm. of hydrogen pressure. After the Pd/C catalyst is isolated by a suction filtration, the residue is concentrated under reduced pressure, and then subjected to flash column chromatography (hexane:ethyl acetate=20:1), so that 11.9 g (40 mmol: 98%) of desired phenyl pyridine alkyl acetal [7] represented by the following formula is obtained.

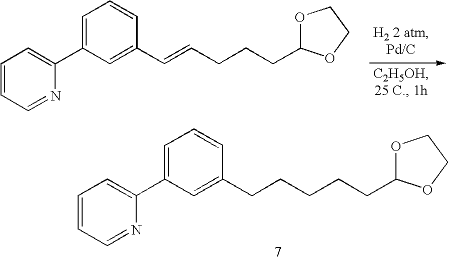

Next, phenyl pyridine alkylic acid chloride [9] is synthesized. 10 g (33.6 mmol) of phenyl pyridine alkyl acetal [7] and 100 mL of 0.5M hydrochloric acid are put into a 300 mL recovery flask (egg plant shaped flask), and then heated to reflux for 2 hours. Then, the mixture is cooled to a room temperature and then extracted with diethyl ether solvent (100 mL×3). The collected organic phase is washed by water, saturated sodium hydrogen carbonate aqueous solution and saturated sodium chloride aqueous solution, and then dried with anhydrous magnesium sulfate. The solvent is distilled away under reduced pressure, so that 9.5 g (30 mmol: 65.6%) of a crude product in an aldehyde form [8] represented by the following formula is obtained.

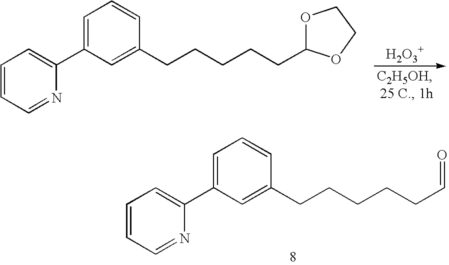

This crude product is mixed with 54 g (45 mmol) of thionyl chloride and a drop of DMF, and gradually heated to reflux for 2 hours in a water bath, while stirring. An excess amount of thionyl chloride is distilled away under reduced pressure, and the mixture is cooled to a room temperature. Then, distillation residue is dissolved into 200 mL of dichloromethane. 100 mL of H₂O is added into this solution with ice-cooling, and stirred sufficiently. An organic phase is separated and a water phase is further extracted with dichloromethane (100 mL×2). The separated organic phase is collected and then washed by water, saturated sodium hydrogen carbonate aqueous solution and saturated sodium chloride aqueous solution, and then dried with anhydrous magnesium sulfate. After the solvent is distilled away under reduced pressure, it is subjected to flash column chromatography (hexane:ethyl acetate=15:1), so that 6.4 g (22 mmol: 65.6%) of adesired phenylpyridine alkylicacid chloride [9] represented by the following formula is obtained.

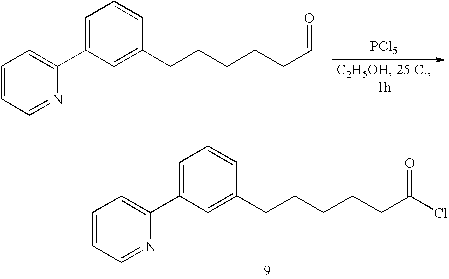

### Synthesis of Ligand [11]

A reacting solution (suspension) is prepared, by putting 1.08 g (8 mmol) of anhydrous aluminum chloride, 30 mL of anhydrous 1,2-dichloroethane, and 4.0 g (6.7 mmol) of n-alkyl CBP, into a three-necked 100 mL flask substituted by argon after dried by heat under reduced pressure. While stirring the reacting solution with ice-cooling in order to maintain the solution at 20° C., 10 mL of 1,2-dichloroethane solution of 2.47 g (8.6 mmol) of phenyl pyridine alkylic acid chloride [9] is dropped into the reacting solution. Then, the reacting solution is stirred for an hour, and left for 12 hours at a room temperature. Then, the reacting solution is poured onto 20 g of ice, so that an organic phase is separated and a water phase is extracted with dichloromethane (20 mL×2). The separated organic phase is collected and then washed by 2% sodiumhydroxide aqueous solution, water, and saturated sodium chloride aqueous solution. Then, the washed organic phase is dried with anhydrous magnesium sulfate, and then concentrated under reduced pressure, so that a crude product is obtained. The crude product is subjected to flash column chromatography (hexane:ethyl acetate=25:1), so that 4.1 g (5 mmol: 75%) of a ketone [10] represented by the following formula is obtained.

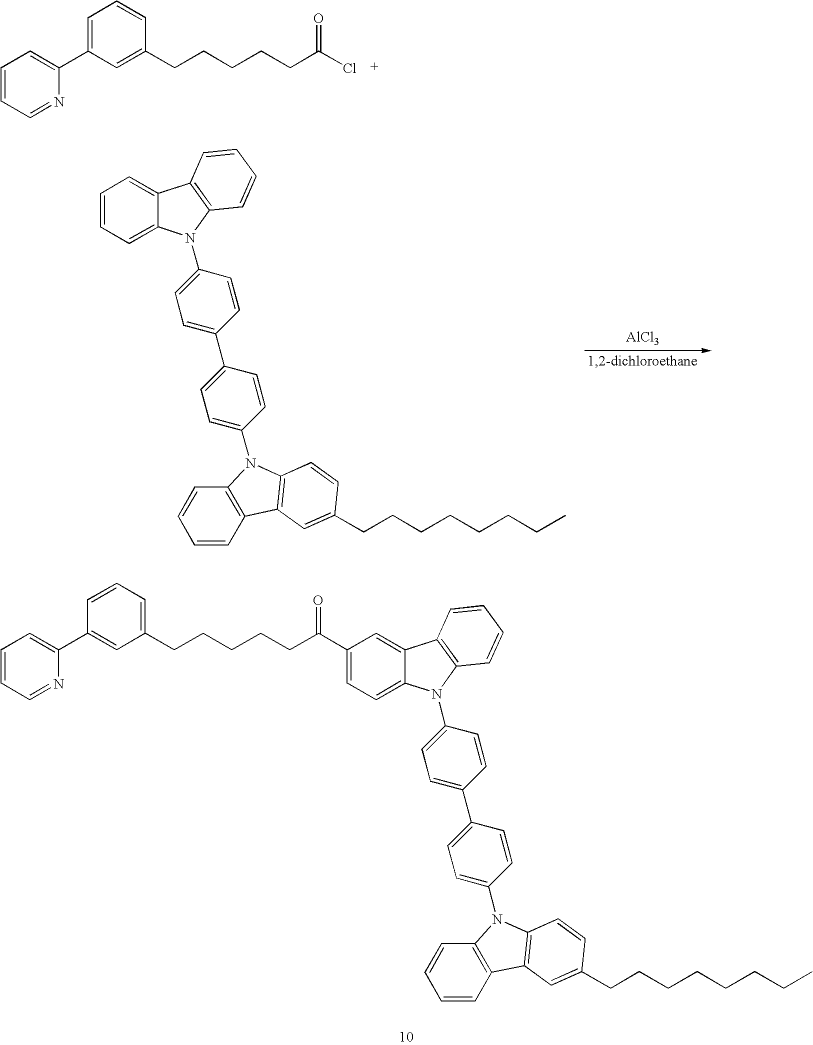

Then, 3.05 g (3.6 mmol) of the obtained ketone [10] is put into a 100 mL recovery flask (egg plant shaped flask) and then 0.72 mL (10.8 mmol) of 80% hydrazine hydrate, 0.65 g of sodium hydroxide, 8 mL of diethylene glycol are mixed to conduct a heating reflux for 2 hours. Then, a heating reflux device is substituted by a distillation head, and the inner temperature is gradually raised to 195 to 200° C. After achieved that temperature, the resultant is maintained at that temperature for 6 hours, so that a mixture of hydrazine and H₂O is distillated. The mixture is cooled and then diluted with 10 mL of water and then extracted with toluene (10 mL×3). The collected organic phase is washed by water and saturated sodium chloride aqueous solution, and then dried with anhydrous magnesium sulfate, and then concentrated under reduced pressure, so that a crude product is obtained. The crude product is subjected to flash column chromatography (hexane:ethyl acetate=25:1), so that 2.4 g (2.9 mmol: 81%) of a ligand [11] represented by the following formula is obtained.

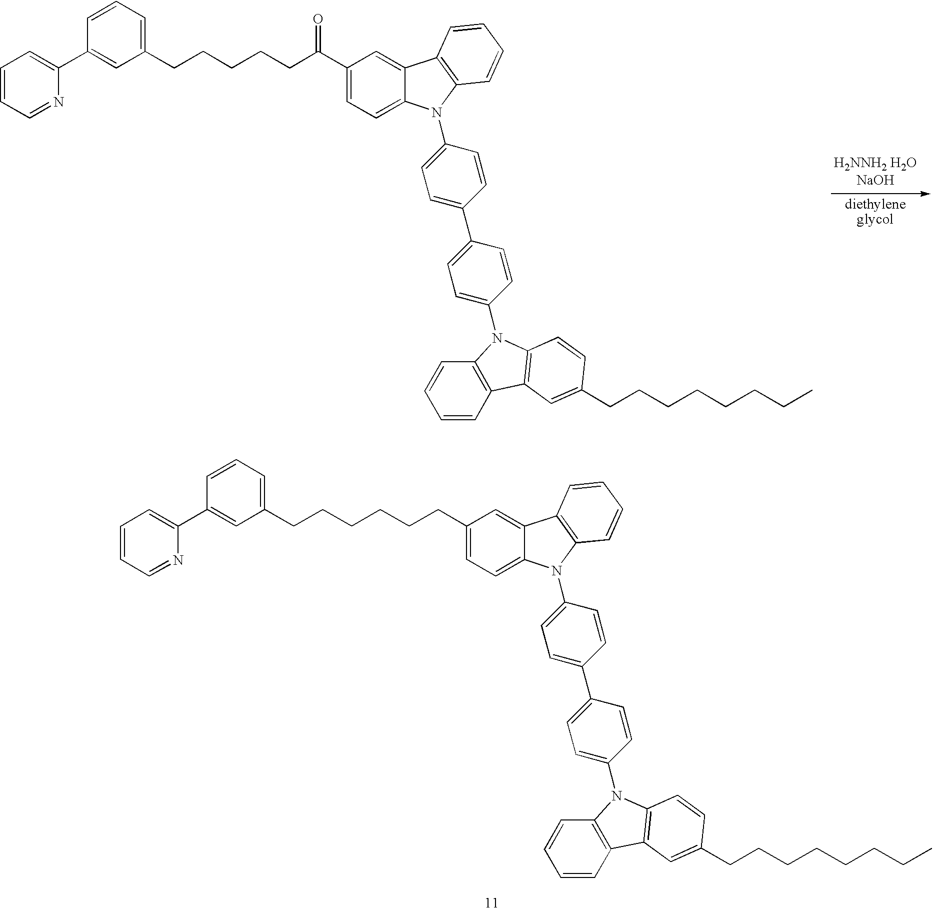

2. Synthesis of Complex

First of all, a precursor is prepared. Iridium chloride trihydrate (0.45 mmol) and 1.66 g (2 mmol) of ligand [11] are put into a three-necked 50 mL flask dried by heat under reduced pressure, so that they are dissolved into 12.2 mL of 2-ethoxyethanol. Distilled water 4 mL is added to the solution, and the solution is stirred at 135° C. for 24 hours, under a gas stream of nitrogen. After the reaction is completed, the sediment is recovered by a glass filter, and then washed by ethanol (20 mL), and then vacuum-dried (80° C., 5 hours), so that 0.8 g (0.2 mmol: 89%) of a crude product in a dimer [12] represented by the following formula is obtained.

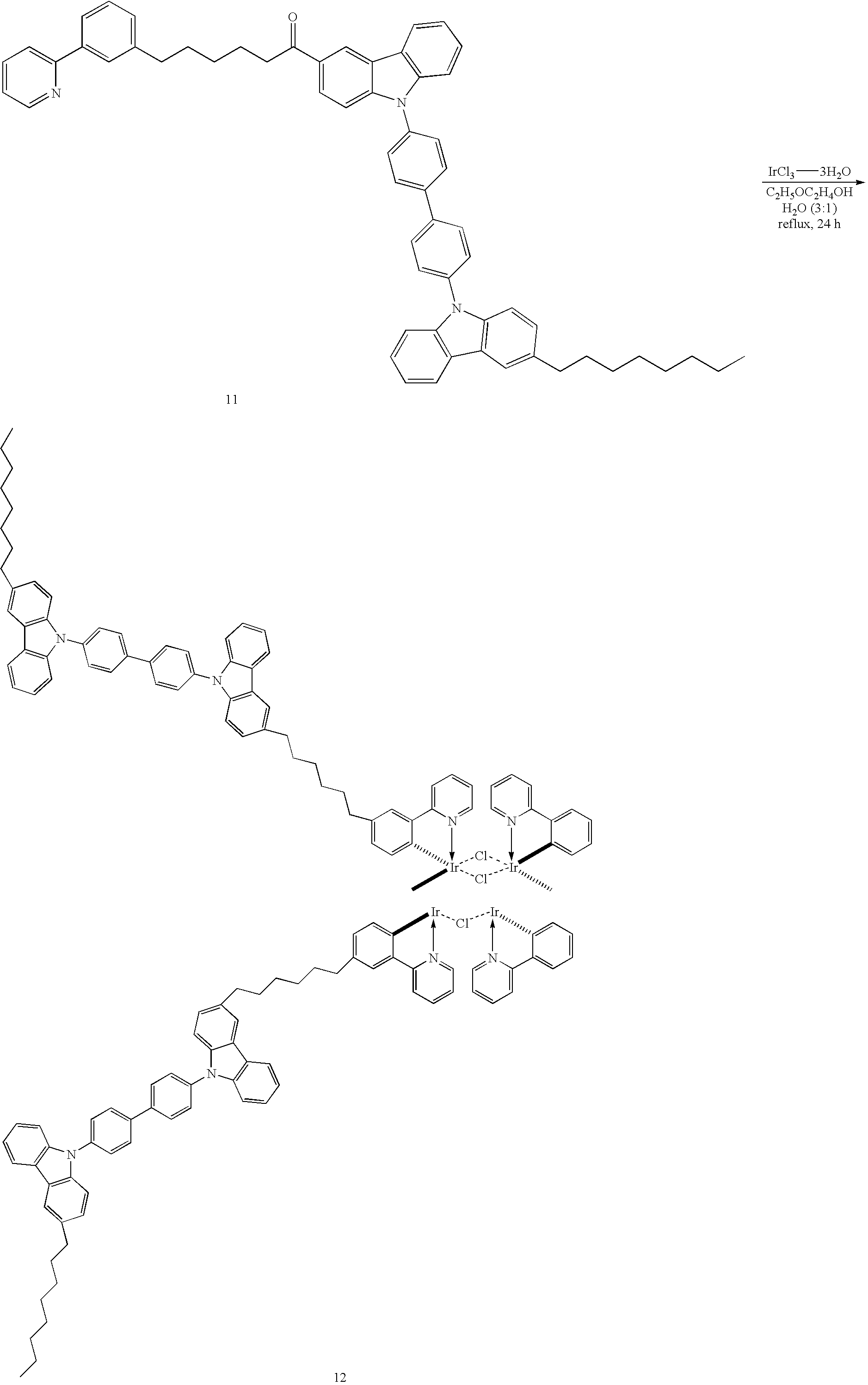

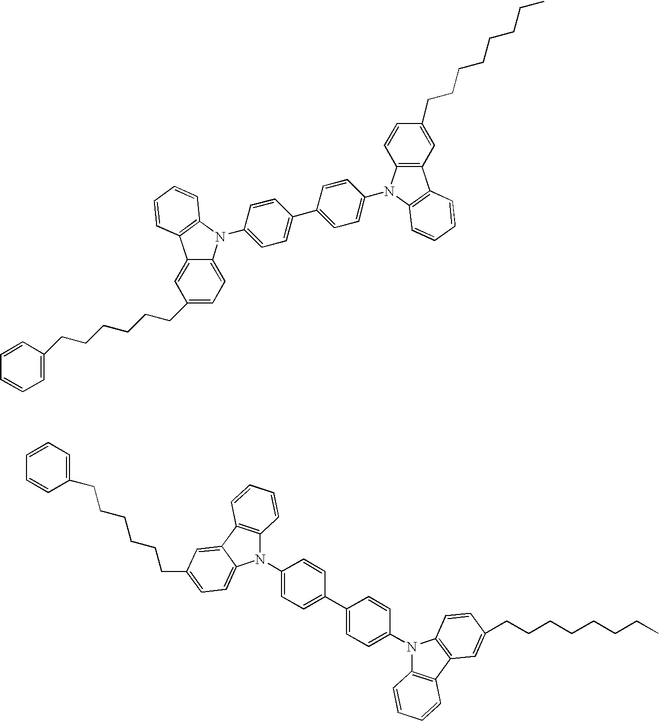

Ethoxyethanol 70 mL, the dimer [12] 0.8 g (0.2 mmol), acetylacetone 0.22 g (2.10 mmol) and sodium carbonate 0.3 g (2.91 mmol) are put into a three-necked 200 mL flask, and they are stirred at a room temperature for an hour under a gas stream of argon. Then, they are stirred by a reflux for 15 hours. The reacting mixture is cooled with ice, and the sediment is filtered and washed with water. This sediment is purified by a silica gel column chromatography (eluent: chloroform/methanol=30/1), and then recrystallized with ethanol, so that 0.20 g (0.18 mmol: yield 45%) of a yellow powder of an iridium complex [13] represented by the following formula is obtained (this complex is referred to as “the organic compound 1” of the present invention). By the aid of a mass spectrometer (MALDI-TOF MS), a value 1962.63, which is a MH⁺ value of this compound, is confirmed. Furthermore, with regard to the structure of the organic compound 1 of the present invention, ¹H-NMR, ¹³C-NMR and IR spectrum exhibit a corresponding spectrum of this compound, respectively.

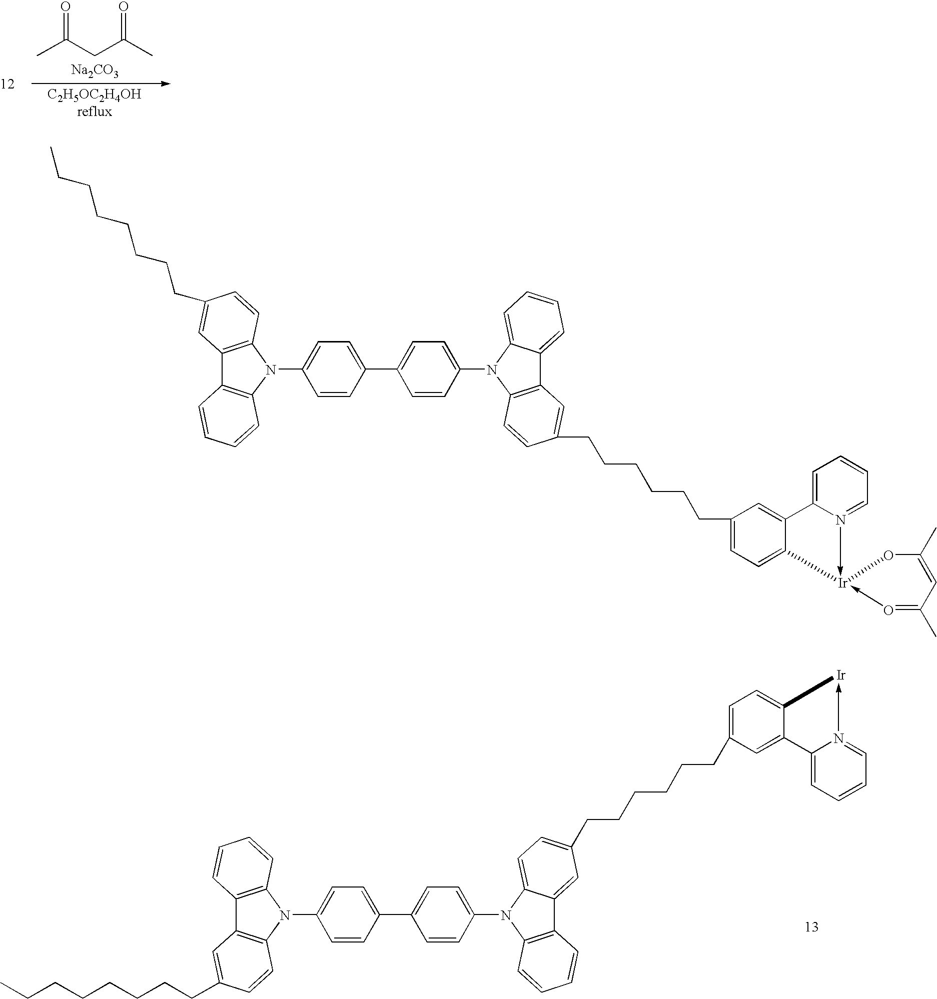

### Example 2

### Synthesis of Organic Compound 2 of the Present Invention

In this example 2, in the compound represented by the aforementioned general formula (1), EM is an iridium coordination compound, X is —CH₂OCH₂—, and CTM is CBP. As the reagent, the following is used without refining, including: phosphorus tribromide, which is purchased from Wako Pure Chemical Industries, Ltd.; 4-(2-pyridyl)benzaldehyde, which is purchased from ALDRICH; phosphorous oxychloride, which is purchased from KANTO CHEMICAL CO., INC.; and others the same as Example 1.

1. Synthesis of Ligand

### Synthesis of 4-hydroxymethyl PPY [21]

A magnetic stirrer and 10.0 g (54.6 mmol) of 4-(2-pyridyl)benzaldehyde are put into a 100 mL recovery flask being attached with a calcium chloride tube, so that they are dissolved into anhydrous ethanol (22 mL). While cooling with ice, 1.1 g (28 mmol) of sodium borohydride is added into the flask and then stirred at a room temperature for an hour. Ice-cooled water (30 mL) is dropped into the flask, and ethanol is distilled away under reduced pressure. After dichloromethane (400 mL) is added and dissolved, the residue is washed by water (300 mL×3) and saturated sodium chloride aqueous solution (300 mL), and the solvent is distilled away under reduced pressure. After a vacuum dry, 10.0 g (54 mmol: 99%) of a crude product of 4-hydroxymethyl PPY [21] is obtained as a colorless solid.

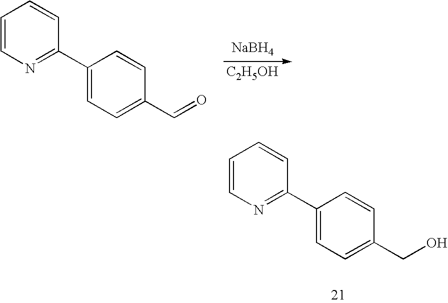

### Synthesis of 4-bromomethyl PPY [22]

The obtained crude produt, 10.0 g (54 mmol) of 4-hydroxymethyl PPY [21], and anhydrous toluene (100 mL) are put into a three-necked 300 mL flask being attached with a reflux tube under a gas stream of nitrogen. Into this, 2.12 mL (22.5 mmol) of phosphorus tribromide is dropped with strong stirring, and then heated to 120° C., and then stirred for an hour. The reacting mixture cooled to a room temperature is poured into a 2 L beaker containing therein water (750 mL) and toluene (750 mL), while the beaker is ice-cooled. An organic phase is separated and a water phase is extracted with toluene (500 mL×3). The separated organic phase is collected and then washed by saturated sodium chloride aqueous solution, and then dried with anhydrous magnesium sulfate, and then concentrated under reduced pressure. Via a vacuum dry, 8.0 g (32.2 mmol: 59%) of a crude product of 4-bromomethyl PPY [22] is obtained as a lemon yellow solid.

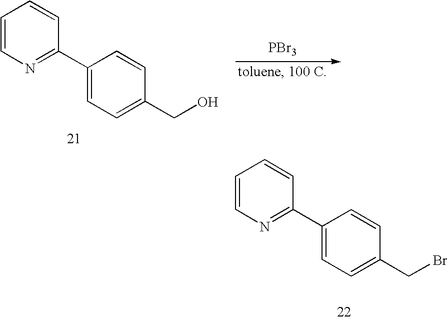

### Synthesis of 3-formyl CBP [23]

A magnetic stirrer, 38.8 g (0.8 mol) of CBP, 187 mL (2.4 mol) of anhydrous DMF and 300 mL of anhydrous chloroform are put into a three-necked 1 L flask being attached with 200 mL dropping funnel and a reflux tube. While they are heated to reflux at 70° C., 100 g (61 mL: 0.65 mol) of phosphorous oxychloride is dropped into the flask for an hour. After the dropping, the reacting mixture is subjected to further 6hours of such a heating reflux. After the reacting mixture is cooled to a room temperature, it is poured little by little into 750 mL of 15% sodium carbonate aqueous solution, with ice-cooling. An organic phase is separated and a water phase is extracted with chloroform (500 mL×4). The separated organic phase is collected and then washed by saturated sodium chloride aqueous solution, and then dried with anhydrous magnesium sulfate, and then concentrated under reduced pressure. Via a vacuum dry, a crude product is obtained. The crude product is subjected to flash column chromatography and then recrystallized from chloroform/ethanol, so that 11.3 g (22 mmol: 27%) of 3-formyl CBP [23] is obtained as a colorless needle-like crystal.

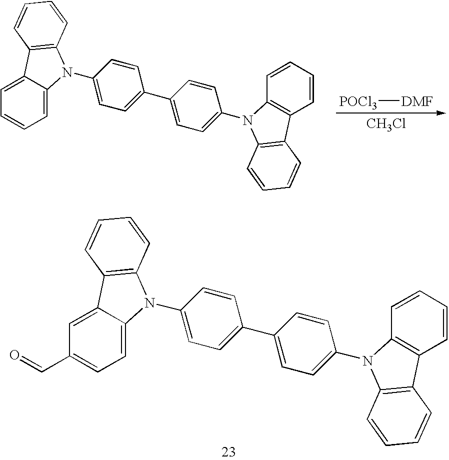

### Synthesis of 3-hydroxymethyl CBP [24]

A magnetic stirrer, 2.5 g (4.9 mmol) of 3-formyl CBP [23] and anhydrous THF (250 mL) are put into a 500 mL recovery flask being attached with a calcium chloride tube. While cooling with ice, 204 mg (5.4 mmol) of sodium borohydride is added into the flask and then stirred at a room temperature for an hour. Anhydrous ethanol (50 mL) is added into the reacting mixture as a colorless suspension, and then stirred for another one hour. Then, this colorless transparent reacting mixture is concentrated under reduced pressure and dissolved into chloroform (500 mL). This solution is washed by water and saturated sodium chloride aqueous solution and then dried with anhydrous magnesium sulfate, and then concentrated under reduced pressure. Via a vacuum dry, 2.5 g (4.8 mmol: 99%) of a crude product of 3-hydroxymethyl CBP [24] is obtained as a colorless solid.

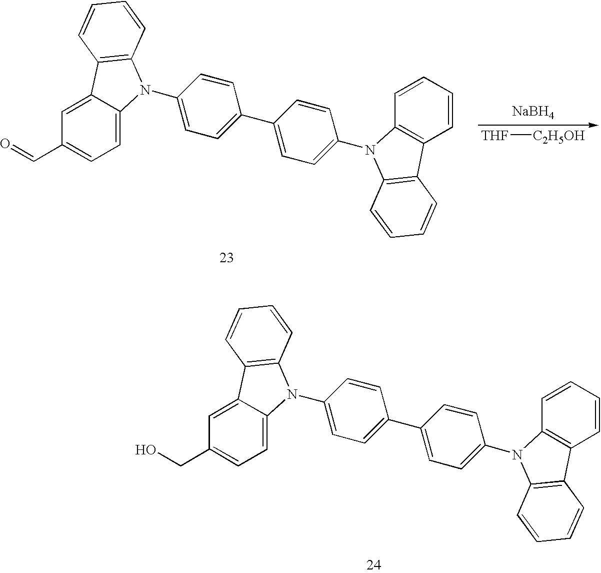

### Synthesis of Ligand, 4-PPY—CH₂OCH₂—CBP [25]

A magnetic stirrer and 192 mg of sodium hydride (55% paraffin suspension: 8 mmol) are put into a three-necked 200 mL flask being attached with a reflux tube. With ice-cooling, anhydrous DMF (40 mL) and 1.84 g (3.6 mmol) of 3-hydroxymethyl CBP [24] are added into the flask, and then stirred for 20 minutes after backed to a room temperature. 21.0 g (4 mmol) of 4-bromomethyl PPY [22] is added to the brown-white color reacting mixture and then stirred at a room temperature for 2 hours. With ice-cooling, methanol is dropped into the mixture, and water and dichloromethane are added. The mixture is washed by saturated sodium chloride aqueous solution and an organic phase is separated. A water phase is extracted with dichloromethane (100 mL×5). The separated organic phase is collected and then washed by saturated sodium chloride aqueous solution, and then dried with anhydrous magnesium sulfate, and then concentrated under reduced pressure. After a vacuum dry, a crude product is obtained as a dark brown solid. The crude product is subjected to flash column chromatography, so that 1.6 g (2.3 mmol: 66%) of 4-PPY—CH₂OCH₂—CBP [25] is obtained as a colorless amorphous solid.

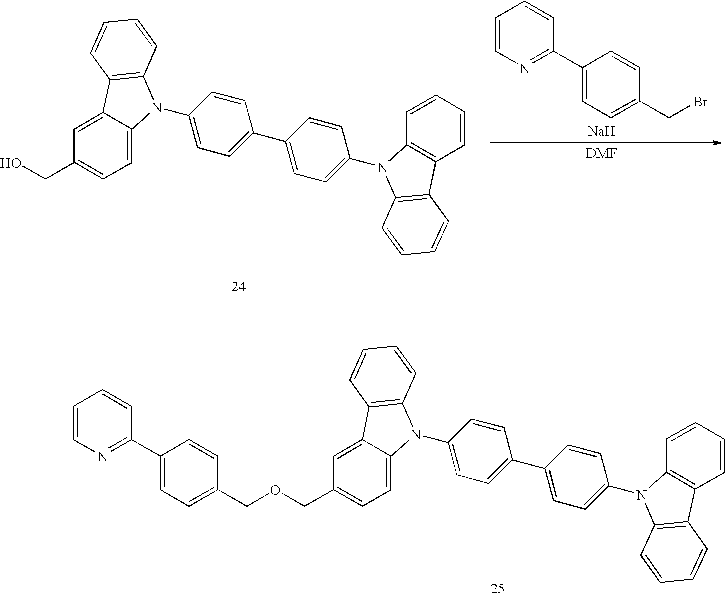

2. Synthesis of Complex

### Synthesis of [IrCl (4-PPY-CH₂—CH₂—CBP)₂]₂ [26]

A magnetic stirrer is put into a 50 mL Schlenk type reacting tube and dried by heat under reduced pressure, and the reacting system is substituted by argon gas. Into there, 2-ethoxyethanol (24 mL), and distilled water (8 mL) are put, and then freeze-deaerated by three times. Then, 1.0 g (1.5 mmol) of 4-PPY-CH₂OCH₂—CBP [25] and 273 mg (0.77 mmol) of iridium chloride (III) trihydrate are put into the reacting tube and heated to reflux at 140° C. for 24 hours. The reacting mixture is cooled to a room temperature, and then the precipitated yellow solid is filtered by a glass filter and then washed by ethanol and aceton. This resultant is dissolved into dichloromethane and filtered. To this filtrate, toluene and hexane are added. Then, this solution is concentrated under reduced pressure, until a volume of the solution becomes 30 mL. After a filtration and washing with hexane, 0.95 g (0.30 mmol: 78%) of [IrCl (4-PPY—CH₂OCH₂—CBP)₂]₂ [26] is obtained as a yellow solid.

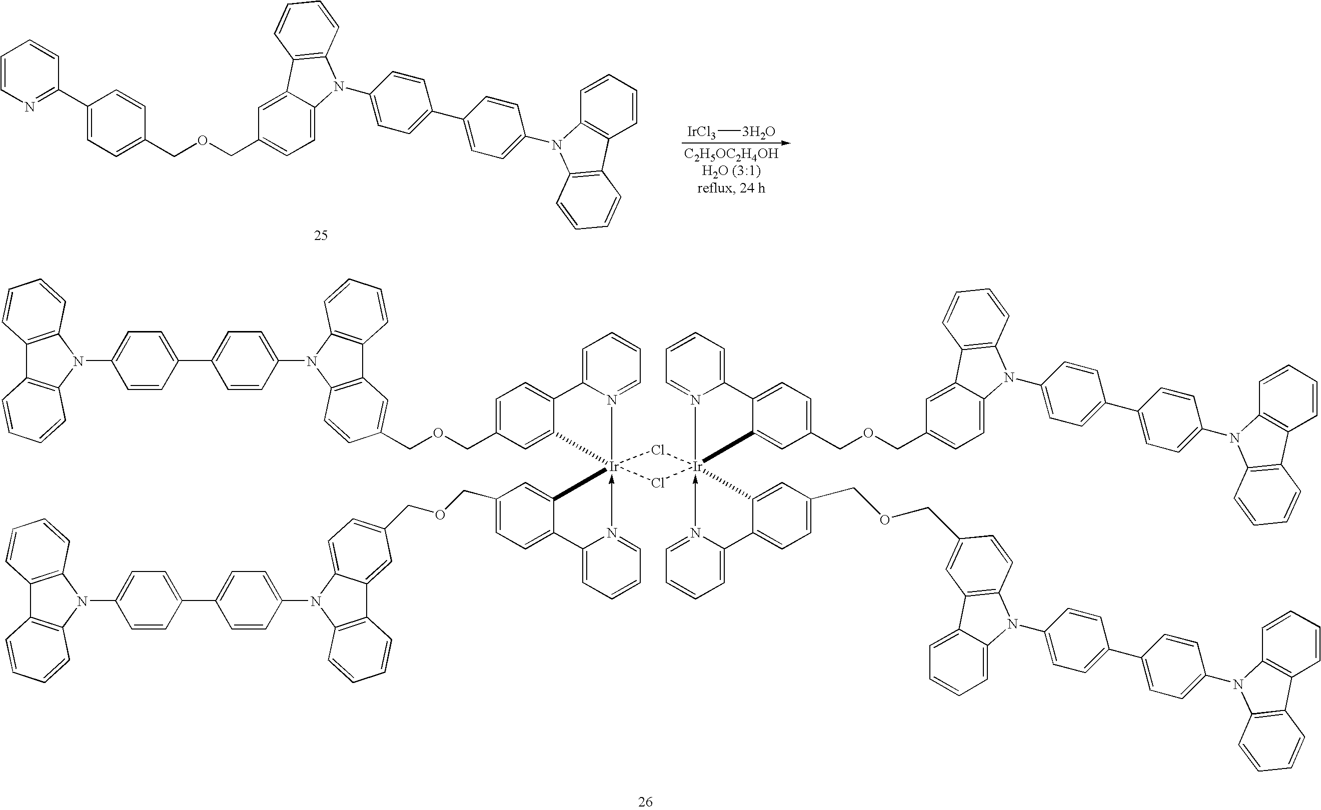

### Synthesis of Ir (acac) (4-PPY-CH₂OCH₂—CBP)₂ [27]

A magnetic stirrer is put into a 50 mL Schlenk type reacting tube and dried by heat under reduced pressure, and the reacting system is substituted by argon gas. Into there, 2-ethoxyethanol (35 mL), and acetyl acetone (0.5 mL) are put, and then freeze-deaerated by three times. Then, 0.95 g (0.30 mmol) of [IrCl (4-PPY—CH₂OCH₂—CBP)₂]₂ [26] and 516 mg (4.9 mmol) of anhydrous sodium carbonate are put into the reacting tube and heated and stirred at 95°C. for 24 hours. The reacting mixture is cooled to a room temperature, and ethanol is added to this mixture, and the precipitated yellow solid is filtered by a glass filter and then washed by ethanol and water. This resultant is dissolved into dichloromethane and filtered. The obtained filtrate is concentrated under reduced pressure. This resultant is subjected to flash column chromatography, and re-sedimented from chloroform/hexane, so that 0.51 g (0.31 mmol: 51%) of Ir (acac) (4-PPY—CH₂OCH₂—CBP)₂ [27] is obtained as a yellow powder (this powder is referred to as “the organic compound 2” of the present invention). By the aid of a mass spectrometer (MALDI-TOF MS), a value 1653.96, which is a MH⁺ value of this compound, is confirmed. Furthermore, with regard to the structure of the organic compound 2 of the present invention, ¹H-NMR, ¹³C-NMR and IR spectrum exhibit a corresponding spectrum of this compound, respectively.

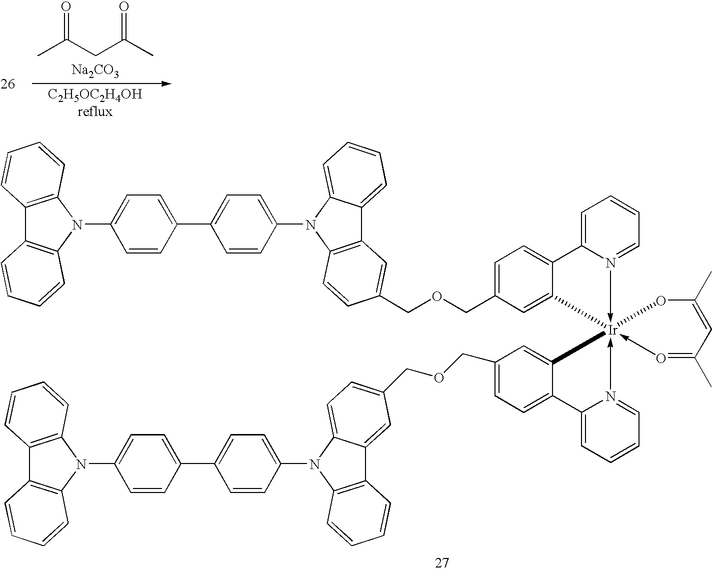

### Example 3

### Synthesis of Organic Compound 3 of the Present Invention

In this example 3, in the compound represented by the aforementioned general formula (1), EM is an iridium coordination compound, X is —CH₂CH₂—, and CTM is CBP. As the reagent, the same as those of examples 1 and 2 is used.

1. Synthesis of Ligand

### Synthesis of Ligand, 4-PPY—CH═CH—CBP [31]

A magnetic stirrer is put into a three-necked 200 mL flask being attached with a reflux tube, and the reacting system is heated and dried under reduced pressure. Into there, 23.6 g (14.6 mmol) of 4-bromomethyl PPY [22] and 2.5 mL (14.6 mmol) of triethyl phosphite are put and then heated at 180° C. for 30 minutes. The reacting mixture in a brown oil form are cooled to a room temperature. THF (120 mL) and 672 mg of sodium hydride (55% paraffin suspension: 15.4 mmol) are added to the reaction mixture and then stirred for 15 minutes. Then, 4.8 g (9.4 mmol) of 3-formyl CBP [23] obtained by the same manner as Example 2 is added to this brown suspension, and then heated to reflux at 75° C. for 2 hours. Ice is added to the reacting mixture which is changed to a black-brown solution, in order to stop the reaction. A precipitated solid is dissolved into dichloromethane, and water and 20% sodium carbonate aqueous solution are added to this solution. An organic phase is separated and a water phase is extracted with dichloromethane (300 mL×5). The separated organic phase is collected and then dried with anhydrous magnesium sulfate, and then concentrated under reduced pressure. After a vacuum dry, a composition is obtained as a black-brown oil form. This oil-like composition is subjected to flash column chromatography, and recrystallized from chloroform/ethanol, so that 4.9 g (7.4 mmol: 51%) of 4-PPY—CH═CH—CBP [31] is obtained as lemon yellow powder.

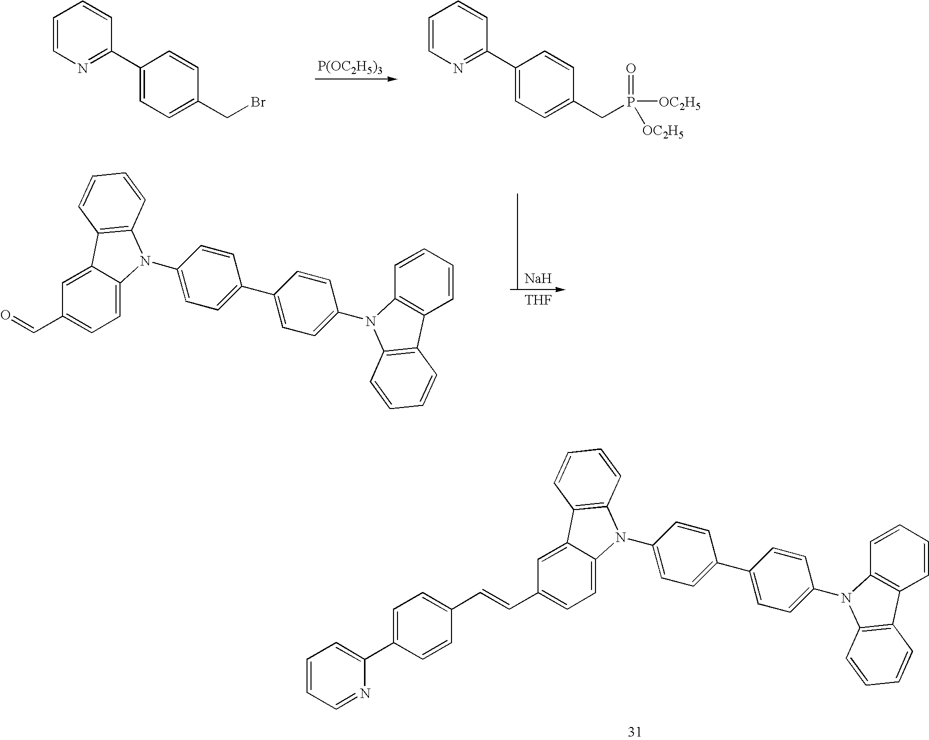

### Ligand, 4-PPY—CH₂CH₂—CBP [32]

A magnetic stirrer is put into a 1000 mL recovery flask. Furthermore, 4.0 g (6.0 mmol) of 4-PPY—CH═CH—CBP [31], THF (300 mL) and 2.5 mg of Pd/C catalyst are put into this flask. The reaction system is substituted by hydrogen gas and stirred at a room temperature for 2 days, under 1.1 atm. of hydrogen atmosphere. The reacting mixture is filtrated using celite, and the filtrate is poured into methanol (500 mL) and reprecipitated, so that 3.5 g (5.3 mmol: 87%) of 4-PPY—CH₂CH₂—CBP [32] is obtained as colorless powder.

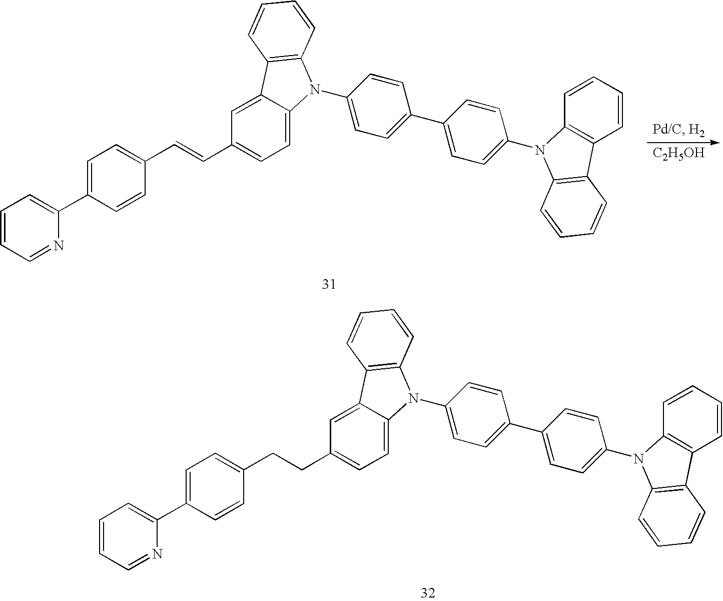

2. Synthesis of Complex

### Synthesis of [IrCl (4-PPY—CH₂CH₂—CBP)₂]₂ [32]

A magnetic stirrer is put into a 50 mL Schlenk type reacting tube and dried by heat under reduced pressure, and the reacting system is substituted by argon gas. Into there, 2-ethoxyethanol (33 mL), and distilled water (11 mL) are put, and then freeze-deaerated by three times. Then, 1.5 g (2.3 mmol) of 4-PPY—CH₂CH₂—CBP [32] and 418 mg (1.2 mmol) of iridium chloride (III) trihydrate are put into the reacting tube and heated to reflux at 140° C. for 24 hours. The reacting mixture is cooled to a room temperature, and then the precipitated yellow solid is filtered by a glass filter and then washed by ethanol and acetone. This resultant is dissolved into dichloromethane and filtered. To this filtrate, toluene and hexane are added. Then, this solution is concentrated under reduced pressure, until a volume of the solution becomes 30 mL. After a filtration and washing with hexane, 1.5 g (0.48 mmol: 81%) of [IrCl (4-PPY—CH₂CH₂—CBP)₂]₂ [33] is obtained as a yellow solid.

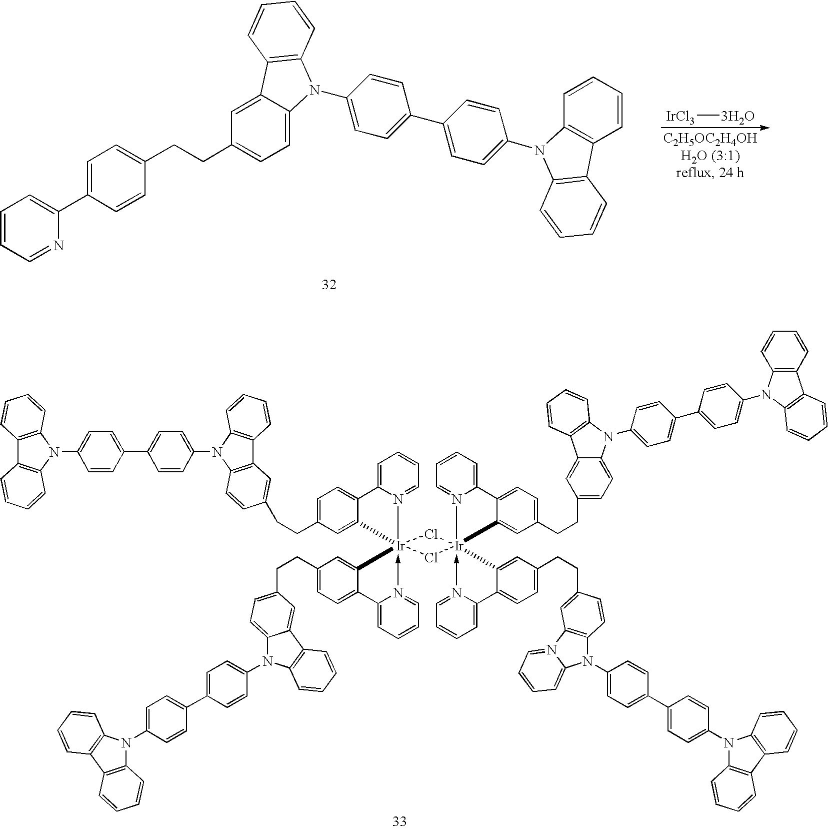

### Synthesis of [Ir(acac)(4-PPY—CH₂CH₂—CBP)₂[34]

A magnetic stirrer is put into a 50 mL Schlenk type reacting tube and dried by heat under reduced pressure, and the reacting system is substituted by argon gas. Into there, 2-ethoxyethanol (40 mL), and acetyl acetone (0.5 mL) are put, and then freeze-deaerated by three times. Then, 1.0 g (0.32 mmol) of [IrCl (4-PPY—CH₂CH₂—CBP)₂]₂ [33] and 550 mg (5.2 mmol) of anhydrous sodium carbonate are put into the reacting tube and heated to be stirred at 95° C. for 24 hours. The reacting mixture is cooled to a room temperature, and ethanol is added to this mixture, and then the precipitated yellow solid is filtered by a glass filter and then washed by ethanol and H₂O. This resultant is dissolved into dichloromethane and filtered. The obtained filtrate is concentrated under reduced pressure. This resultant is subjected to flash column chromatography and then reprecipitated from chloroform/hexane, so that 0.3 g (0.18 mmol: 28%) of [Ir (acac) (4-PPY—CH₂CH₂—CBP)₂ [34] isobtained asyellow powder (this product is referred to as “the organic compound 3” of the present invention). By the aid of a mass spectrometer (MALDI-TOF MS), a value 1621.96, which is a MH⁺ value of this compound, is confirmed. Furthermore, with regard to the structure of the organic compound 3 of the present invention, ¹H-NMR, ¹³C-NMR and IR spectrum exhibit a corresponding spectrum of this compound, respectively.

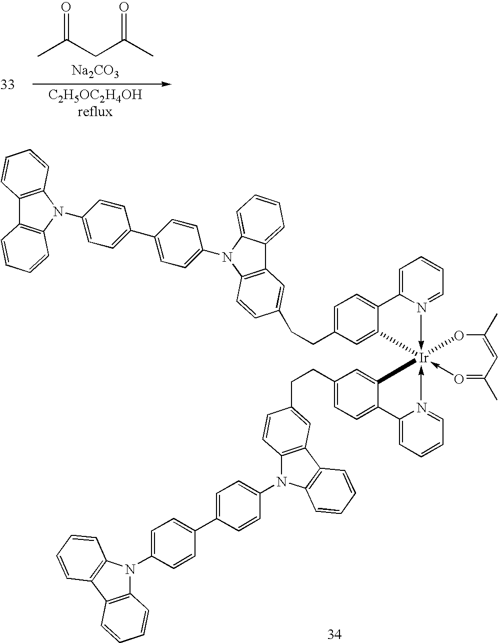

### Example 4

### Synthesis of Organic Compound 4 of the Present Invention

In this example 4, in the compound represented by the aforementioned general formula (1), EM is an iridium coordination compound, X is —CH₂—BC—CH₂CH₂— including a cycloaliphatic compound (abbreviated as BC), and CTM is CBP. As the reagent, the following is used without refining, including: endo-bicyclo[2,2,2]oct-5en-2,3-dicarboxylic anhydride, which is purchased from Acros Organics; bromo-benzene, which is purchased from TOKYO KASEI KOGYO CO., LTD.; anhydrous diethyl ether, aluminum lithium hydride, and 2-methoxymethyl ether, which are purchased from KANTO CHEMICAL CO., INC.; and others which are the same as those of examples 1, 2 and 3.

1. Synthesis of Ligand

### Synthesis of Ketocarboxylic Acid [41]

A suspension is prepared by putting 5.3 g (40 mmol) of anhydrous aluminum chloride, anhydrous 1,2-dichloromethane (100 mL) and 3.8 g (36 mmol) of bromobenzene into a three-necked 100 mL flask substituted by argon gas after dried by heat under reduced pressure. With ice-cooling, 7.1 g (40 mol) of endo-bicyclo[2,2,2]oct-5en-2,3-dicarboxylic anhydride is dropped into this suspension, so as to maintain a temperature of this suspension at 20° C. Then, the suspension (reacting solution) is stirred for an hour and left at a room temperature for 12 hours. This reacting solution is poured onto ice (20 g), and acidified by concentrated hydrochloric acid. From this, the organic phase is separated. The water phase is extracted with dichloromethane (50 mL×3). The separated organic phase is collected and then washed by saturated sodium chloride aqueous solution. The washed organic phase is then dried with anhydrous magnesium sulfate, and then concentrated under reduced pressure. Via a re-crystallization from DMF/water, 7.8 g (23 mmol: 65%) of ketocarboxylic acid [41] is obtained.

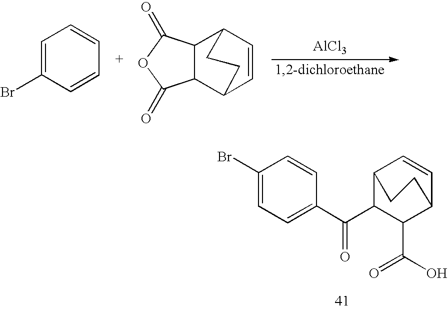

### Synthesis of Aldehyde [42]

The obtained ketocarboxylic acid [41] 7.5 g (22 mmol) is put into a 100 mL recovery flask and then 1.8 mL (27 mmol) of 80% hydrazine hydrate, 1.8 g of sodium hydroxide, 22 mL of diethylene glycol are mixed to conduct a heating reflux for 2 hours. Then, a heating reflux device is substituted by a distillation head, and the inner temperature is gradually raised to 195 to 200° C. After achieved that temperature, the reactant is maintained at that temperature for 6 hours, so that a mixture of hydrazine and H₂O is distillated. The mixture is cooled and then diluted with 35 mL of water, and then acidified by concentrated hydrochloric acid, and then extracted with dichloromethane (100 mL×3). The collected organic phase is washed by water and saturated sodium chloride aqueous solution, and then dried with anhydrous magnesium sulfate, and then concentrated under reduced pressure, and then re-crystallized from DMF/water, so that 5.6 g (17.6 mmol: 80%) of carboxylic acid is obtained.

This carboxylic acid 5.6 g (17.6 mmol) is mixed with 24 g (20 mmol) of thionyl chloride and a drop of DMF, and gradually heated to reflux for 2 hours in a water bath, with stirring. An excess amount of thionyl chloride is distilled away under reduced pressure, and the residue is cooled to a room temperature and dissolved into 100 mL of dichloromethane solvent. Into this solution, 50 mL of water is added with ice-cooling and then stirred sufficiently. An organic phase is separated and a water phase is further extracted with dichloromethane (100 mL×2). The separated organic phase is collected and then washed by water, saturated sodium hydrogen carbonate aqueous solution and saturated sodium chloride aqueous solution, and then dried with anhydrous magnesium sulfate. After the solvent is distilled away under reduced pressure, the residue is subjected to flash column chromatography, so that 3.9 g (11.6 mmol: 66%) of acidic chloride is obtained.

Aluminum lithium hydride 0.42 g (11 mmol) is suspended into anhydrous diethyl ether (25 mL). Into this suspension, 2.6 g (35.2 mmol) of t-butyl alcohol is dropped. The precipitated alkoxy dihydride alminium salt is sufficiently sedimented to remove diethyl ether. 2-methoxy ethyl ether (9 mL) is added to the precipitate.

Acidic chloride 3.7 g (11 mmol) is dissolved into 2-methoxy methyl ether (5.0 mL). Into this, Li[HAl(Ot-C₄H₉)₃] solution is dropped for an hour, with stirring at −70 to −75° C. After the dropping, this solution is stirred for another one hour and then filtered. The filtered reacting solution is extracted with hot ethanol and re-crystallized, so that 2.2 g (7.4 mmol: 67%) of aldehyde [42] is obtained.

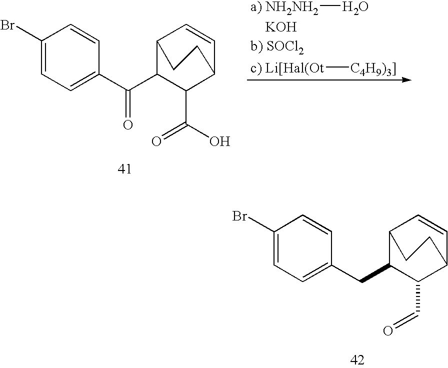

### Synthesis of 4-PPY—CH₂—BC—CHO [43]

The obtained aldehyde [42] is acetalized by using ethylene glycol, and then 2.0 g (5.7 mmol) of the acetalized aldehyde is dissolved into 30 mL of THF, and then cooled to −78° C. under nitrogen atmosphere. Into this, 2.8 mL (7.0 mmol: 2.5 M) of n-butyllithium is dropped to cause a reaction for an hour. After the reaction, 2.8 g (15.0 mmol) of 2-isopropoxy-4,4,5,5-tetramethyl-1,3,2-dioxabororan is added and then continued the reaction for another one hour. After the reaction is completed, the mixture is cooled to a room temperature, and then stirred for 30 minutes, and then extracted with diethyl ether, so that a boronic acid ester is obtained.

The obtained boronic acid ester, 2-bromopyridine (7.0 mmol) and Pd(PPh₃)₄ (0.35 mmol) are dissolved into 50 mL of THF. Into this solution, 105 mL (2M) of potassium carbonate aqueous solution is poured, and then stirred at 60° C. for 10 hours under gas stream of nitrogen. After the reaction is completed, acetalized phenyl pyridine is obtained via an extraction with diethyl ether.

A mixture of the obtained acetalized phenyl pyridine and 0.5M hydrochloric acid (100 mL) is heated to reflux for 45 minutes, with stirring. After cooling, the reacting mixture is extracted with diethyl ether and the organic phase is washed by water, saturated sodium hydrogen carbonate aqueous solution and saturated sodium chloride aqueous solution, and then dried with anhydrous magnesium sulfate, and then concentrated under reduced pressure. Via re-crystallization from hexane/chloroform, so that 1.3 g (4.5 mmol: 79%) of4-PPY—CH₂—BC—CHO [43] is obtained.

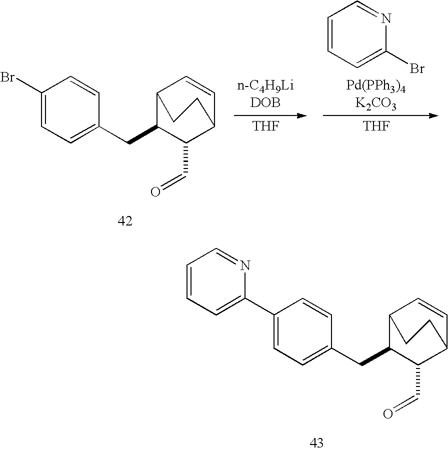

### Synthesis of 4-PPY—CH₂—BC—CH═CH—CBP [45]

A magnetic stirrer is put into a three-necked 200 mL flask attached with a reflux tube and dried by heat under reduced pressure. Into there, 1.0 g (3.3 mmol) of 3-CBP—CH₂Br[44] and 0.57 mL (3.3 mmol) of triethyl phosphite are put, and then heated at 180° C. for 30 minutes. Incidentally, 3-CBP—CH₂Br[44) is obtained by bromizing 3-hydroxymethyl CBP [24] of Example 2 with phosphorus tribromide. The reacting mixture in a brown oil form is cooled to a room temperature. Into this, 25 mL of anhydrous THF and 148 mg (3.4 mmol) of 55% sodium hydride in mineral oil suspension are added and then stirred for 15 minutes. Then, 1.0 g (3.3 mmol) of 4-PPY—CH₂—BC—CHO[43] is added to this brown suspension, and then heated to reflux at 75° C. for 2 hours. Ice is added to the reacting mixture, which is changed into a black-brown solution, in order to stop the reaction. The precipitated solid is dissolved into dichloromethane (100 mL). Into this, water (100 mL) and 20%sodiumcarbonate aqueoussolution (100 mL) are added. An organic phase is separated and a water phase is extracted with dichloromethane (100 mL×5). The separated organic phase is collected and then dried with anhydrous magnesium sulfate, and then concentrated under reduced pressure. After a vacuum dry, a composition in a black-brown oil form is obtained. This composition is subjected to flash column chromatography, and re-crystallized from chloroform/ethanol, so that 1.3 g (1.7 mmol: 51%) of 4-PPY—CH₂—BC—CH═CH—CBP[45] is obtained as lemon yellow powder.

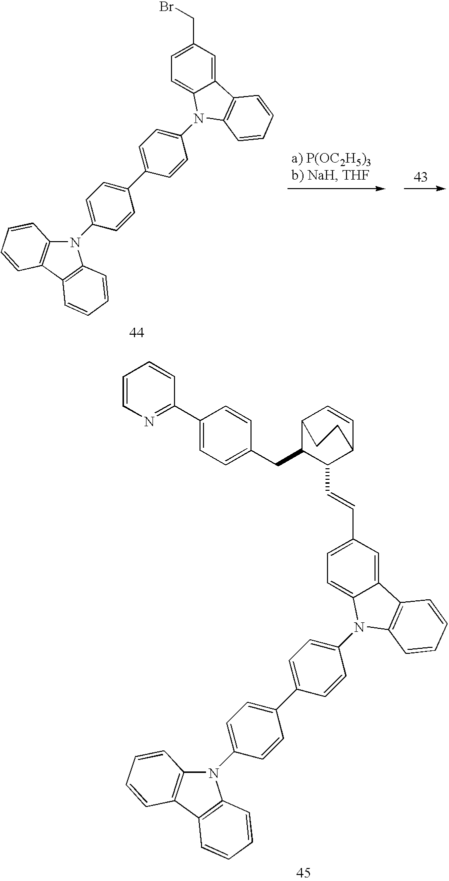

### Synthesis of 4-PPY—CH₂—BC—CH₂CH₂—CBP [46]

A magnetic stirrer is put into a 50 mL recovery flask. Into there, 1.3 g (1.7 mmol) of 4-PPY—CH₂—BC—CH═CH—CBP[45], 100 mL of THF, and 2.5 mg of palladium carbon are put. The reacting system is substituted by hydrogen gas, and then stirred at a room temperature for 2 days, under 1.1 atm. of hydrogen atmosphere. The reacting mixture is filtrated using celite. After palladium carbon is removed, the filtrate is poured into methanol (300 mL), and reprecipitated, so that 1.3 g (1.6 mmol: 95%) of 4-PPY—CH₂—BC—CH₂CH₂—CBP [46] is obtained as colorless powder.

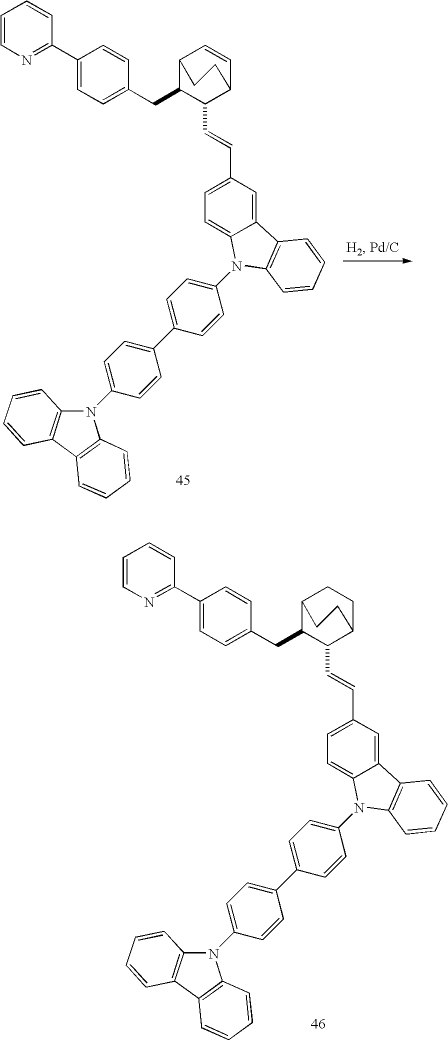

2. Synthesis of Complex

### Synthesis of [IrCl (4-PPY—CH₂—BC—CH₂CH₂—CBP)₂]₂ [47]

A magnetic stirrer is put into a 50 mL Schlenk type reacting tube and dried by heat under reduced pressure, and the reacting system is substituted by argon gas. Into there, 23 mL of 2-ethoxyethanol and 7.7 mL of distilled water are put and freeze-deaerated by three times. Then, 1.3 g (1.6 mmol) of 4-PPY—CH₂—BC—CH₂CH₂—CBP [46] and 291 mg (0.84 mmol) of iridium chloride (III) trihydrate are put into the reacting tube and heated to reflux at 140° C. for 24 hours. The reacting mixture is cooled to a room temperature, and then the precipitated yellow solid is filtered by a glass filter and then washed by ethanol and acetone. This resultant is dissolved into dichloromethane and filtered. To this filtrate, toluene and hexane are added. Then, this solution is concentrated under reduced pressure, until a volume of the solution becomes 25 mL. After a filtration and washing with hexane, 1.2 g (0.33 mmol: 79%) of [IrCl (4-PPY—CH₂—BC—CH₂CH₂—CBP)₂]₂ [47] is obtained as a yellow solid.

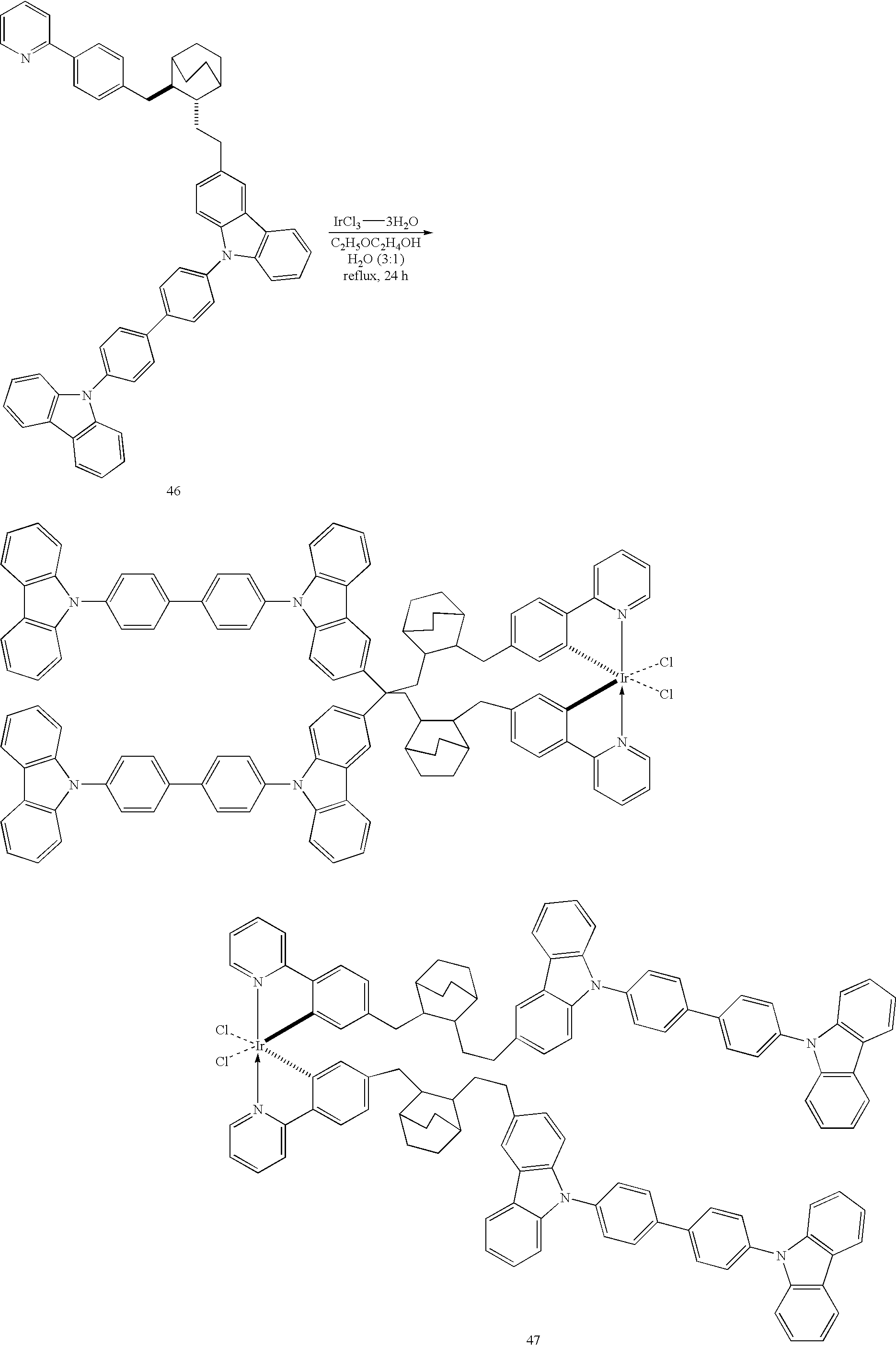

### Synthesis of Ir (acac) (4-PPY—CH₂—BC—CH₂CH₂—CBP)₂ [48]

A magnetic stirrer is put into a 50 mL Schlenk type reacting tube and dried by heat under reduced pressure, and the reacting system is substituted by argon gas. Into there, 42 mL of 2-ethoxyethanol and 0.5 mL of acetyl acetone are put and freeze-deaerated by three times. Then, 1.2 g (0.33 mmol) of [IrCl (4-PPY—CH₂—BC—CH₂CH₂—CBP)₂]₂ [47] and 567 mg (5.41 mmol) of anhydrous sodium carbonate are put into the reacting tube and heated to reflux at 95° C. for 24 hours. The reacting mixture is cooled to a room temperature, and ethanol is added to this, and then the precipitated yellow solid is filtered by a glass filter and then washed by ethanol and water. This resultant is dissolved into dichloromethane and filtered. The obtained filtrate is concentrated under reduced pressure. The resultant is subjected to flash column chromatography and then reprecipitated from chloroform/hexane, so that 0.2 g (0.1 mmol: 16%) of Ir (acac) (4-PPY—CH₂—BC—CH₂CH₂—CBP)₂ [48] is obtained as yellow powder (this product is referred to as “the organic compound 4” of the present invention). By the aid of a mass spectrometer (MALDI-TOF MS), a value 1861.34, which is a MH⁺ value of this compound, is confirmed. Furthermore, with regard to the structure of the organic compound 4 of the present invention, ¹H-NMR, ¹³C-NMR and IR spectrum exhibit a corresponding spectrum of this compound, respectively.

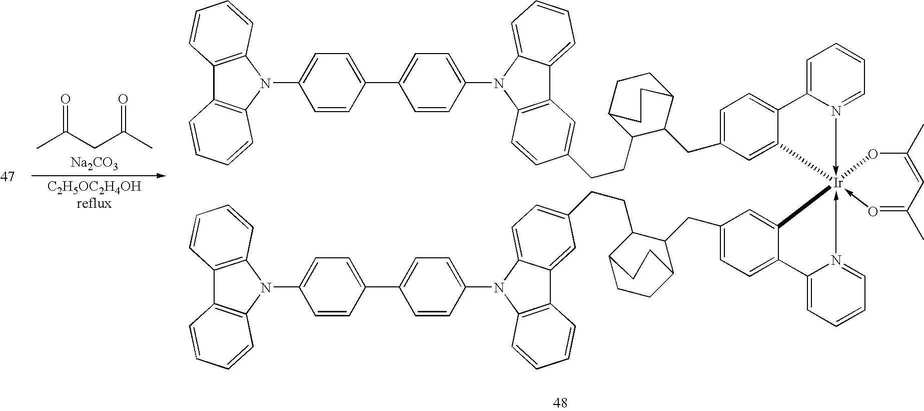

### Comparative Example 1

### Synthesis of Ir (acac) (ppy)₂)

### Synthesis of [IrCl (ppy)₂]₂

A magnetic stirrer is put into a 50 mL Schlenk type reacting tube and dried by heat under reduced pressure, and the reacting system is substituted by argon gas. Into there, 31 mL of 2-ethoxyethanol and 10 mL of distilled water are put and freeze-deaerated by three times. Then, 0.75 mL (5.3 mmol) of 2-phenyl pyridine and 516 mg (1.46 mmol) of iridium chloride (III) trihydrate are put into the reacting tube and heated to reflux at 140° C. for 24 hours. The reacting mixture is cooled to a room temperature, and then the precipitated yellow solid is filtered by a glass filter and then washed by ethanol and acetone. This resultant is dissolved into dichloromethane and filtered. To this filtrate, toluene and hexane are added. Then, this solution is concentrated, until a volume of the solution becomes 25 mL. After a filtration and washing with hexane, 0.69 g (0.33 mmol: 79%) of [IrCl(ppy)₂]₂ is obtained as a yellow solid.

### Synthesis of Ir (acac) (ppy)₂

2-phenyl pyridine is purchased from ALDRICH, and other agents is the same as those of Examples 1, 2, 3 and 4.

A magnetic stirrer is put into a 50 mL Schlenk type reacting tube and dried by heat under reduced pressure, and the reacting system is substituted by argon gas. Into there, 33 mL of 2-ethoxyethanol and 0.13 mL of acetyl acetone are put and freeze-deaerated by three times. Then, 0.55 g (0.52 mmol) of [IrCl (ppy)₂]₂and 169 mg (1.34 mmol) of anhydrous sodium carbonate are put into the reacting tube and heated to reflux at 95° C. for 24 hours. The reacting mixture is cooled to a room temperature, and ethanol is added to this, and then the precipitated yellow solid is filtered by a glass filter and then washed by ethanol and water. This resultant is dissolved into dichloromethane and filtered. The obtained filtrate is concentrated under reduced pressure. The resultant is subjected to flash column chromatography and then reprecipitated from chloroform/hexane, so that 0.2 g (0.1 mmol: 16%) of Ir (acac) (PPY)₂ is obtained as yellow powder. By the aid of a mass spectrometer (MALDI-TOF MS), a value 601.71, which is a MH⁺ value of this compound, is confirmed. Furthermore, with regard to the structure of this organic compound, ¹H-NMR, ¹³C-NMR and IR spectrum exhibit a corresponding spectrum of this compound, respectively.

### Calculation of Conformation for Examples 1 to 4

The following values are calculated, including a shortest distance sum AˆB of interatomic distances from the atom A to the atom B via a neighboring atom on X, a linear distance A−B between the atom A and the atom B, and a ratio represented by (AˆB)/(A−B), under conditions that an atom in EM bonded to X is referred to as an atom A, and an atom in CTM bonded to X is referred to as an atom B. Incidentally, the intermolecular distance and the linear distance are calculated on the basis of a structure obtained by an optimization of a compound structure, using a calculation software CAChe Worksystem Ver. 5.0 (Fujitsu), in a molecular mechanics method, MM3 (“CRC Handbook of Chemistry and Physics,” 60th Edition, R. C. Weast, (Ed.), CRC Press, Boca Raton, Fla., 1980. M. W. Chase, C. A. Davies, J. R. Downey, D. R. Frurip, R. A. McDonald, A. N. Syverud, JANAF Thermochemical Tables, Third Edition, J. Phys. Chem. Ref. Data 14, Suppl. 1 (1985). NIST Chemistry WebBook, NIST Standard Reference Database, No. 69; W. G. Mallard, P. J. Linstrom, Eds., National Institute of Standards and Technology, Gaithersberg, http://webbook.nist.gov/chemistry. J. O. Cox, G. Pilcher, “Thermochemistry of Organic and Organometallic Compounds,” Academic Press, New York, N.Y., 1970. P. v. R. Schleyer, J. E. Williams, K. R. Blanchard, J. Am. Chem. Soc., 92, 3277, (1970).). The result is shown in Table 1.

TABLE 1

| | | A\hat{ }B(Å) | A − B(Å) | A\hat{ }B/A − B |
|---|---|---|---|---|
| Example | Ir(acac) (4-ppy- | 10.7 | 8.8 | 1.2 |
| 1 | (CH₂)₆-cbp-C₈H₁₇)₂ | | | |
| Example | Ir(acac) (4-ppy- | 5.9 | 5.0 | 1.2 |
| 2 | CH₂OCH₂-cbp)₂ | | | |
| Example | Ir(acac) (4-ppy- | 4.6 | 3.9 | 1.2 |
| 3 | (CH₂)₂-cbp)₂ | | | |
| Example | Ir(acac) | 9.2 | 4.4 | 2.1 |
| 4 | (4-ppy-BC-cbp)₂ | | | |

### Evaluation of Examples 1 to 4 and Comparative Examples 1 to 3

Properties are evaluated for the organic compounds 1 to 4 of Examples 1 to 4, Ir (acac) (ppy)₂ of Comparative Example 1, Ir 8 ppy (produced by CHEMIPRO KASEI KAISHA, LTD.) as Comparative Example 2, which is taken in view of its solubility and whose structure is shown below, and Ir (ppy)₃ (produced by CHEMIPRO KASEI KAISHA, LTD.) as Comparative Example 3.

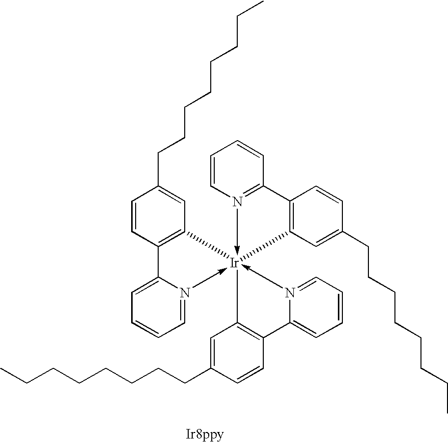

(1) Solubility Test

Solubility tests are conducted using: toluene and xylene as an aromatic solvent; chloroform and 1,2-dichloroethane as a halogenated hydrocarbon solvent; and tetrahydrofuran as an ether solvent. The organic compounds 1 to 4 obtained by Examples 1 to 4, respectively, Ir (acac) (ppy)₂ as Comparative Example 1, Ir 8 ppy as Comparative Example 2 and Ir (ppy)₃ as Comparative Example 3 are mixed with 5 mL of each of the above-listed solvent, and each mixture is stirred at a room temperature for 30 minutes, so that each soluble concentration by weight is evaluated. The result is shown in Table 2.

[Evaluation Criteria]

◯: Soluble at 1.0% by mass or more.
Δ: Soluble at 0.1% by mass or more, but less than 1.0% by mass.

×: Soluble only less than 0.1% by mass.

TABLE 2

| | | | | | 1,2-dichloro | |
|---|---|---|---|---|---|---|
| | | Xylene | Toluene | Chloroform | ethane | THF |
| Ex. 1 | Ir(acac)(4-ppy-(CH₂)₆-cbp-C₈H₁₇)₂ | ◯ | ◯ | ◯ | ◯ | ◯ |
| Ex. 2 | Ir(acac)(4-ppy-CH₂OCH₂-cbp)₂ | ◯ | ◯ | ◯ | ◯ | ◯ |
| Ex. 3 | Ir(acac)(4-ppy-(CH₂)₂-cbp)₂ | ◯ | ◯ | ◯ | ◯ | ◯ |
| Ex. 4 | Ir(acac)(4-ppy-BC-cbp)₂ | ◯ | ◯ | ◯ | ◯ | ◯ |
| Comp. 1 | Ir(acac)ppy₂ | X | X | ◯ | Δ | ◯ |
| Comp. 2 | Ir₈ppy | ◯ | ◯ | ◯ | ◯ | ◯ |
| Comp. 3 | Ir(ppy)₃ | X | X | ◯ | Δ | ◯ |

The organic compounds 1 to 4 of the present invention exhibit a good solubility, respectively, even in cases of aromatic solvents into which compounds of Comparative Examples 1 and 3 are difficult to dissolve.

(2) Heat Resistance Test

TG/DTA measurements are conducted, using an apparatus, TG-DTATG8120 (fabricated by Rigaku Corporation), under nitrogen gas atmosphere, temperature rising speed=5.0° C./min, for the organic compound 1 to 4 obtained by Examples 1 to 4, respectively, and Ir (acac) (ppy)₂ as Comparative Example. On the basis of the obtained each TG/DTA curve, a temperature, at which a 5% weight loss is appeared, is compared among those samples. The result is shown in Table 3.

TABLE 3

| | | Δ T_{5%} (° C.) |
|---|---|---|
| Ex. 1 | Ir(acac)(4-ppy-(CH₂)₆-cbp-C₈H₁₇)₂ | 260 |
| Ex. 2 | Ir(acac)(4-ppy-CH₂OCH₂-cbp)₂ | 230 |
| Ex. 3 | Ir(acac)(4-ppy-(CH₂)₂-cbp)₂ | 300 |
| Ex. 4 | Ir(acac)(4-ppy-BC-cbp)₂ | 350 |
| Comp. 1 | Ir(acac)ppy₂ | 243 |

The organic compounds 1 and 3, in which X is alkyl straight chain, exhibit higher heat resistance than that of the conventional compound as Comparative Example 1. On the other hand, the organic compound 2 including an ether bond exhibits lower heat resistance than that of the conventional compound as Comparative Example 1, and the reason thereof is considered because of dissociation of the ether bond. The organic compound 4, in which X has a more rigid cycloaliphatic compound, exhibits still higher heat resistance. The organic compounds exhibiting higher heat resistance are expected to be an advantage for elongating life, in cases that they are used as organic EL element materials.

### Examples 5 to 8

### Production of Organic EL Element

Organic EL elements of Examples 5 to 8 are produced from the organic compounds 1 to 4 of the present invention, which are obtained by Examples 1 to 4. First of all, a substrate comprising a transparent conductive film of ITO formed on a glass substrate is patterned into a predetermined pattern, and then subjected to washing and UV/ozone treatment. Then, poly-3,4-ethylene dioxy thiophen/polystyrenesulfonate aqueous dispersion (abbreviated as “PEDOT/PPS”, known as a commercial name, Baytron TP CH8000, from Bayer) is dropped onto the washed substrate to spin-coat the substrate. Then, the substrate is heated and dried on a hot plate of 200° C., for 10 minutes, so that a positive hole transporting layer of 80 nm in thickness is formed. Then, the organic compound of the present invention and CBP polymer (Japanese Patent Application Laid-Open Nos. 2003-008873 and 2003-008874) as a charge transporting material are mixed into xylene at the following composition ratio to form a composition for an electron transporting and light emitting layer, and this mixture (composition ratio: as for solid portion, the organic compound of the present invention (Ir atom converted)/charge transporting group (CBP molecular converted)=4/96 (mol ratio), and ratio of the solid portion is 1.5% by mass) is dropped to spin-coat the substrate, so that an electron transporting and light emitting layer of 40 nm in thickness is formed.

Furthermore, under a vacuum condition of 5.0×10⁻⁶ Torr, metal calcium is vacuum-deposited until 10 nm, at a deposition speed, 0.14 nm/s. Above this, silver is further vacuum-deposited until 250 nm, at a deposition speed, 0.23 nm/s, so that an electrode is formed.

### Comparative Examples 4 and 5

### Production of Organic EL Element

For a purpose of comparison, organic EL elements of Comparative Examples 4 and 5 are produced, using materials of Comparative Examples 1 and 2. First of all, a substrate comprising a transparent conductive film of ITO formed on a glass substrate is patterned into a predetermined pattern, and then subjected to washing and UV/ozone treatment. Then, poly-3,4-ethylene dioxy thiophen/polystyrenesulfonate aqueous dispersion (abbreviated as “PEDOT/PPS”, known as a commercial name, Baytron TP CH8000, from Bayer) is dropped onto the washed substrate to spin-coat the substrate. Then, the substrate is heated and dried on a hot plate of 200° C., for 10 minutes, so that a positive hole transporting layer of 80 nm in thickness is formed. Then, the material of Comparative Examples 1 or 2 and CBP polymer (Japanese Patent Application Laid-Open Nos. 2003-008873 and 2003-008874) as a charge transporting material are mixed into xylene at the following composition ratio to form a composition for an electron transporting and light emitting layer, and this mixture (composition ratio: as for solid portion, the organic compound of the present invention (Ir atom converted)/charge transporting group (CBP molecular converted)=4/96 (mol ratio), and ratio of the solid portion is 1.5% by mass) is dropped to spin-coat the substrate, so that an electron transporting and light emitting layer of 40 nm in thickness is formed.

### Comparative Example 6

### Production of Low Molecular Deposition Type Organic EL Element

For a purpose of comparison, organic EL elements of Comparative Example 6 is produced, using the material of Comparative Example 3. The material of Comparative Example 3 agglomerates in a short time, when used in a coating process, resulting in an unstable film. Therefore, a deposition process is employed.

First of all, a substrate comprising a transparent conductive film of ITO formed on a glass substrate is patterned into a predetermined pattern, and then subjected to washing and UV/ozone treatment. Then, poly-3,4-ethylene dioxy thiophen/polystyrenesulfonate aqueous dispersion (abbreviated as “PEDOT/PPS”, known as a commercial name, Baytron TP CH8000, from Bayer) is dropped onto the washed substrate to spin-coat the substrate. Then, the substrate is heated and dried on a hot plate of 200° C., for 10 minutes, so that a positive hole transporting layer of 80 nm in thickness is formed.

Then, under a vacuum condition of 4.0×10⁻⁶ Torr, CBP (produced by CHEMIPRO KASEI KAISHA, LTD.) and Ir (ppy)₃ are deposited until 40 nm each, at a deposition speed, 0.3 nm/s, and 0.02 nm/s, respectively.

Furthermore, under a vacuum condition of 5.0×10⁻⁶ Torr, metai calcium is vacuum-deposited until 10 nm, at a deposition speed, 0.14 nm/s. Above this, silver is further vacuum-deposited until 250 nm, at a deposition speed, 0.23 nm/s, so that an electrode is formed.

### Evaluation of Examples 5 to 8, and Comparative Examples 4 to 6

### Evaluation of Organic EL element

(1) Brightness of Element

An external power source (Source Meter 2400 fabricated by Keithley Instruments Inc.) is connected to the organic EL element produced as mentioned above, and direct voltage is applied to the element under a condition that ITO is an anode and the metal electrode is a cathode, so that a green light emission is obtained due to Ir (acac) (ppy)₂ or Ir (ppy)₃. The brightness of element is measured by using a brightness photometer (“BM-8” fabricated by TOPCON CORPORATION). The result of obtained maximum brightness is shown in Table 4.

TABLE 4

| | | Brightness |
|---|---|---|
| | Used Organic Compound | (Cd/m²) |
| Ex. 5 | Ir(acac)(4-ppy-(CH₂)₆-cbp-C₈H₁₇)₂ | 4000 |
| Ex. 6 | Ir(acac)(4-ppy-CH₂OCH₂-cbp)₂ | 3400 |
| Ex. 7 | Ir(acac)(4-ppy-(CH₂)₂-cbp)₂ | 3500 |
| Ex. 8 | Ir(acac)(4-ppy-BC-cbp)₂ | 4500 |
| Comp. 4 | Ir(acac)ppy₂ | 2800 |
| Comp. 5 | Ir8ppy | 3000 |
| Comp. 6 | Ir(ppy)₃ *1 | 1680 |

*1 Deposition Process

The organic EL elements of the present invention using the organic compounds of the present invention as light emitting materials exhibit improved brightness, in comparison with cases of using conventional low molecular guest materials.

(2) Current Efficiency

The current efficiency is determined from: a current value obtained from the external power source in the driving state for the brightness test; and the brightness at that time. Maximum current efficiencies obtained for each element are shown in Table 5.

TABLE 5

| | | Current Efficiency |
|---|---|---|
| | Used Organic Compound | (Cd/A) |
| Ex. 5 | Ir(acac)(4-ppy-(CH₂)₆-cbp-C₈H₁₇)₂ | 8 |
| Ex. 6 | Ir(acac)(4-ppy-CH₂OCH₂-cbp)₂ | 5 |
| Ex. 7 | Ir(acac)(4-ppy(CH₂)₂-cbp)₂ | 6.5 |
| Ex. 8 | Ir(acac)(4-ppy-BC-cbp)₂ | 10 |
| Comp. 4 | Ir(acac)ppy₂ | 1 |
| Comp. 5 | Ir8ppy | 4 |
| Comp. 6 | Ir(ppy)₃ *1 | 0.16 |

*1 Deposition Process

The organic EL elements of the present invention using the organic compounds of the present invention as light emitting materials exhibit improved current efficiencies, in comparison with cases of using conventional low molecular guest materials.

(3) Emission Spectrum

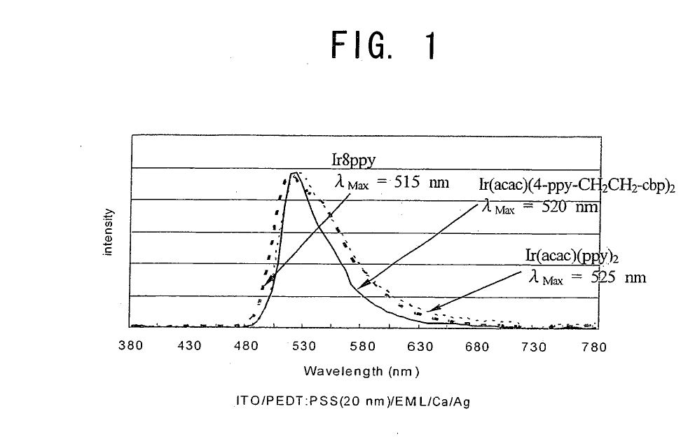

Emission spectra are measured by using a spectroradiometer (“SR-2” fabricated by TOPCON CORPORATION). A result about Example 7 for an element using Ir (acac) (4-ppy-CH₂CH₂-cbp)₂ is shown in FIG. 1. In each organic EL element of Examples 5 to 8, an emission spectrum originated from Ir (acac) (PPY)₂ which has a peak the same as a PL peak is obtained. In each organic EL element of Examples 5 to 8 produced using the organic compounds of the present invention, a spectrum having narrower width than that of the conventional low molecular guest material such as Ir (acac) (PPY)₂ is obtained. Even in comparison with Ir 8ppy having a straight chain octyl group for providing solubility, a spectrum having a narrower width is obtained as for elements of the present invention. From this, it is considered that concentration quenching can be restrained by linking the fluorescent or emitting material to a bulky CBP, and thereby more effectively preventing emission centers from being associated. Thereby, it is expected that the luminous efficiency improves, which may elongate an element life.

### INDUSTRIAL APPLICABILITY

As discussed above, the organic compound of the present invention exhibits superior solubility to solvents owing to an effect of the chemical bonding chain X or the substituent Y to be added. Thereby, it is possible to form a film by using a coating material containing the organic compound. Therefore, it is possible to produce an organic light emitting (electroluminescence) element, especially a phosphorescent light emitting element, by a coating process.

Furthermore, since the organic compound of the present invention disperses without agglomerating in the coating film, it can present a uniform luminescence property at each part on the coated material, when used for the organic EL element. As the result, a uniform light emission or luminescence is presented in a surface, due to injected charges, so that the luminous efficiency improves. Furthermore, the chemical bonding of the organic compound of the present invention optimizes the relative orientation and the intermolecular distance between the host and the guest which are most closely adjacent to each other, as well as acts as a barrier for preventing the charge migration. For this reason, a direct and spatial energy migration can be achieved from the charge transporting material CTM to the light emitting material EM, without passing any cross-linking group. Therefore, the organic compound of the present invention can present higher luminous efficiency, in the case that it is used for the organic EL element.

The organic compound of the present invention has a higher purity than that of a conventional coating type light emitting/phosphorescent light emitting material, and can restrain the agglomeration of the light emitting material itself. This makes an obtained emission/phosphorescent spectrum sharp, and thereby present higher color purity. Furthermore, the organic compound of the present invention is superior in the thermal stability, which is advantageous for elongating a life.

Therefore, the organic compound of the present invention solves the various problems involved within the conventional coating type emission/phosphorescent material, such as problems of purity, intermolecular distance, molecular orientation, and thereby can present the organic EL element having a long life owing to the high efficiency of emission.

Since the organic EL element of the present invention is provided with a layer containing the organic compound of the present invention having the aforementioned effect, it is easy to form a layer, in which the compound is well dispersed, by a coating process, in comparison with a case that a layer, which contains the phosphorescent emitting material and the charge transporting material, mixed with each other as seen in the conventional technique, and can also present higher luminous efficiency, which may elongate the element life.

1. An organic compound represented by the following general formula (1):
EM-X-CTM (1)
wherein, EM is a fluorescent-light emitting material or phosphorescent light emitting material; CTM is a charge transporting material; and X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain.

2. An organic compound represented by the following general formula (2):
(EM-X-CTM)-Y (2)
wherein, EM is a fluorescent light emitting material or phosphorescent light emitting material; CTM is a charge transporting material; X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain; and Y is a substituent introduced at any part of EM, CTM or X for improving at least solubility to a solvent, Y being selected from a group consisting of hydrogen atom, alkyl group, alkoxy group, alkylthio group, alkylsilyl group, alkylamino group, aryl group, arylalkyl group, arylalkoxyl group, arylalkynyl group, arylamino group, heterocyclic group, cyano group, nitro group, and halogen atoms.

3. An organic compound represented by the following general formula (3): 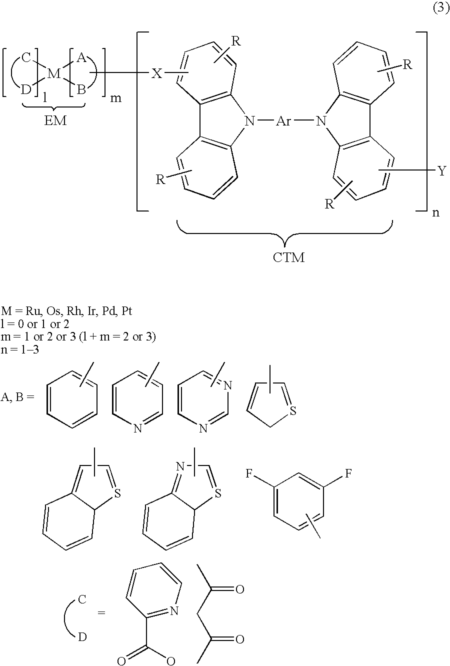
wherein, EM is a fluorescent light emitting material or phosphorescent light emitting material; CTM is a charge transporting material; Ar is a non-substituted or substituted arylene group or a non-substituted or substituted heterocyclic group; each R may be different or same, and selected from the group consisting of hydrogen atom, alkyl group, alkoxy group, alkylthio group, alkylsilyl group, alkylamino group, aryl group, arylalkyl group, arylalkoxy group, arylalkynyl group, arylamino group, heterocyclic group, cyano group, nitro group, and halogen atoms; X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain; and Y is a substituent optionally introduced as an occasion demands for improving at least solubility to a solvent, Y being selected from a group consisting of hydrogen atom, alkyl group, alkoxy group, alkylthio group, alkylsilyl group, alkylamino group, aryl group, arylalkyl group, arylalkoxyl group, arylalkynyl group, arylamino group, heterocyclic group, cyano group, nitro group, and halogen atoms.

4. An organic compound according to claim 1, wherein an intermolecular distance between the EM and the CTM is set at a predetermined distance at which solubility and/or hopping conduction of the organic compound can be maintained.

5. An organic compound according to claim 1, wherein AˆB is 3 Å or more, wherein an atom in EM bonded to X is referred to as an atom A, an atom in CTM bonded to X is referred to as an atom B, and a shortest distance sum of interatomic distances from the atom A to the atom B via a neighboring atom on X is referred to as AˆB.

6. An organic compound according to claim 1, wherein A−B is 2 Å to 50 Å, wherein an atom in EM bonded to X is referred to as an atom A, an atom in CTM bonded to X is referred to as an atom B, and a linear distance between the atom A and the atom B is referred to as A−B.

7. An organic compound according to claim 1, wherein a ratio represented by (AˆB)/(A−B) is 1.1 to 20, wherein an atom in EM bonded to X is referred to as an atom A, an atom in CTM bonded to X is referred to as an atom B, a shortest distance sum of interatomic distances from the atom A to the atom B via a neighboring atom on X is referred to as AˆB, and a linear distance between the atom A and the atom B is referred to as A−B.

8. An organic compound according to claim 1, wherein A−B is 2 Å to 50 Å and (AˆB)/(A−B) is 1.1 to 10, wherein an atom in EM bonded to X is referred to as an atom A, an atom in CTM bonded to X is referred to as an atom B, a shortest distance sum of interatomic distances from the atom A to the atom B via a neighboring atom on X is referred to as AˆB, and a linear distance between the atom A and the atom B is referred to as A−B.

9. An organic compound according to claim 1, wherein said X includes a cycloaliphatic compound.

10. An organic compound according to claim 1, wherein said X includes a cycloaliphatic compound selected from a group consisting of cycloaliphatic compounds selected from a group consisting of cycloaliphatic compounds represented by the following general formula (4):

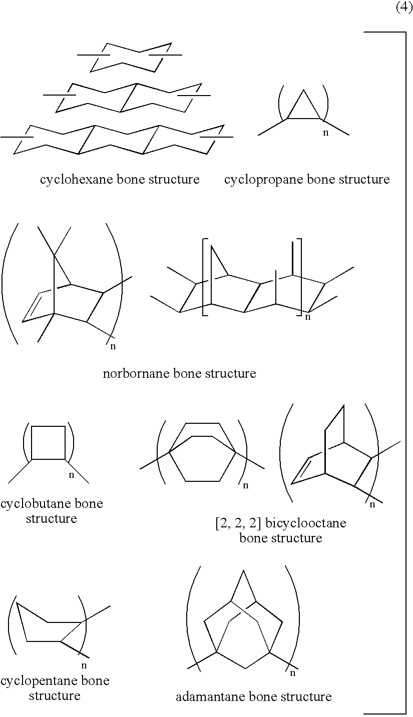

11. An organic compound according to claim 1, wherein said X comprises a hydrocarbon chain containing no hetero atom.

12. An organic compound according to claim 1, wherein said EM is a fluorescent light emission colorant selected from a group consisting of a coumarin derivative, a quinolidine derivative, a quinacridon derivative, a pyrrolopyrrole derivative, a polycyclic aromatic hydrocarbon, a styrylbenzene derivative, polymethine derivative and a xanthene derivative; a fluorescent light emission metallic complex selected from a group consisting of a quinolinol complex derivative, a quinoline complex derivative, a hydroxyphenyl oxazole, a hydroxyphenyl thiazole and an azomethine metallic complex derivative; or a phosphorescent light emission transition metal complex selected from a group consisting of an iridium complex derivative and a platinum complex derivative.

13. An organic compound according to any claim 1, wherein said CTM is a hole transporting material selected from a group consisting of an aromatic tertiary amine derivative, starburst polyamines and a phthalocyanine metallic complex derivative; a charge transporting material selected from a group consisting of an aluminoquinolinol complex derivative, an oxadiazole derivative, a triazole derivative, a triazine derivative and a phenylquinoxalline derivative; or a hole charge transporting material selected from a carbazole biphenyl derivative.

14. An organic electroluminescent element provided with at least a pair of opposite electrodes; and one or more organic compound layers sandwiched between the pair of opposite electrodes, wherein
at least one layer of the organic compound layers contains an organic compound represented by the following general formula (1):
EM-X—CTM (1)
wherein, EM is a fluorescent light emitting material or phosphorescent light emitting material; CTM is a charge transporting material; and X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain.

15. An organic electroluminescent element provided with: at least a pair of opposite electrodes; and one or more organic compound layers sandwiched between the pair of opposite electrodes, wherein
at least one layer of the organic compound layers contains an organic compound represented by the following general formula (2):
(EM-X—CTM)-Y (2)
wherein, EM is a fluorescent light emitting material or phosphorescent light emitting material; CTM is a charge transporting material; X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain; and Y is a substituent introduced at any part of EM, CTM or X for improving at least solubility to a solvent, Y being selected from a group consisting of hydrogen atom, alkyl group, alkoxy group, alkylthio group, alkylsilyl group, alkylamino group, aryl group, arylalkyl group, arylalkoxyl group, arylalkynyl group, arylamino group, heterocyclic group, cyano group, nitro group, and halogen atoms.

16. An organic electroluminescent element provided with: at least a pair of opposite electrodes; and one or more organic compound layers sandwiched between the pair of opposite electrodes, wherein
at least one layer of the organic compound layers contains an organic compound represented by the following general formula (3): 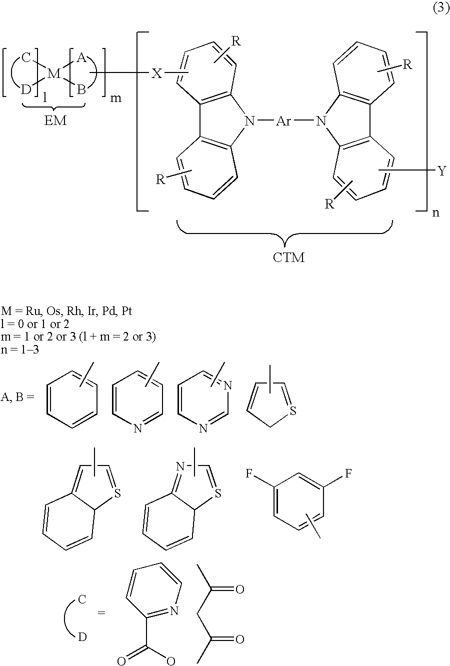
wherein, EM is a fluorescent light emitting material or phosphorescent light emitting material; CTM is a charge transporting material; Ar is a non-substituted or substituted arylene group or a non-substituted or substituted heterocyclic group; each R may be different or same, and selected from the group consisting of hydrogen atom, alkyl group, alkoxy group, alkylthio group, alkylsilyl group, alkylamino group, aryl group, arylalkyl group, arylalkoxy group, arylalkynyl group, arylamino group, heterocyclic group, cyano group, nitro group, and halogen atoms; X is a bivalent organic group composed of a straight, branched or cyclic carbon or hydrocarbon chain or a combination thereof, in which the hydrocarbon chain may include a hetero atom, and in which a substituent may be disposed above a cycle of the cyclic carbon or hydrocarbon chain; and Y is a substituent optionally introduced as an occasion demands for improving at least solubility to a solvent, Y being selected from a group consisting of hydrogen atom, alkyl group, alkoxy group, alkylthio group, alkylsilyl group, alkylamino group, aryl group, arylalkyl group, arylalkoxyl group, arylalkynyl group, arylamino group, heterocyclic group, cyano group, nitro group, and halogen atoms.

17-26. (canceled)

27. An organic electroluminescent element according to claim 14, wherein the compound is mixed with or dispersed within a charge transporting low or high molecular weight material to form a light emitting layer.

28. An organic electroluminescent element according to claim 14, wherein a charge transporting layer is disposed between the organic compound layer and a negative electrode.

29. An organic electroluminescent element according to claim 14, wherein a hole transporting layer is disposed between the organic compound layer and a positive electrode.

30. An organic compound according to claim 2, wherein an intermolecular distance between the EM and the CTM is set at a predetermined distance at which solubility and/or hopping conduction of the organic compound can be maintained.

31. An organic compound according to claim 3, wherein an intermolecular distance between the EM and the CTM is set at a predetermined distance at which solubility and/or hopping conduction of the organic compound can be maintained.

32. An organic compound according to claim 2, wherein AˆB is 3 Å or more, wherein an atom in EM bonded to X is referred to as an atom A, an atom in CTM bonded to X is referred to as an atom B, and a shortest distance sum of interatomic distances from the atom A to the atom B via a neighboring atom on X is referred to as AˆB.

33. An organic compound according to claim 3, wherein AˆB is 3 Å or more, wherein an atom in EM bonded to X is referred to as an atom A, an atom in CTM bonded to X is referred to as an atom B, and a shortest distance sum of interatomic distances from the atom A to the atom B via a neighboring atom on X is referred to as AˆB.

34. An organic compound according to claim 2, wherein A−B is 2 Å to 50 Å, wherein an atom in EM bonded to X is referred to as an atom A, an atom in CTM bonded to X is referred to as an atom B, and a linear distance between the atom A and the atom B is referred to as A−B.

35. An organic compound according to claim 3, wherein A−B is 2 Å to 50 Å, wherein an atom in EM bonded to X is referred to as an atom A, an atom in CTM bonded to X is referred to as an atom B, and a linear distance between the atom A and the atom B is referred to as A−B.

36. An organic compound according to claim 2, wherein a ratio represented by (AˆB)/(A−B) is 1.1 to 20, wherein an atom in EM bonded to X is referred to as an atom A, an atom in CTM bonded to X is referred to as an atom B, a shortest distance sum of interatomic distances from the atom A to the atom B via a neighboring atom on X is referred to as AˆB, and a linear distance between the atom A and the atom B is referred to as A−B.

37. An organic compound according to claim 3, wherein a ratio represented by (AˆB)/(A−B) is 1.1 to 20, wherein an atom in EM bonded to X is referred to as an atom A, an atom in CTM bonded to X is referred to as an atom B, a shortest distance sum of interatomic distances from the atom A to the atom B via a neighboring atom on X is referred to as AˆB, and a linear distance between the atom A and the atom B is referred to as A−B.

38. An organic compound according to claim 2, wherein A−B is 2 Å to 50 Å and (AˆB)/(A−B) is 1.1 to 10, wherein an atom in EM bonded to X is referred to as an atom A, an atom in CTM bonded to X is referred to as an atom B, a shortest distance sum of interatomic distances from the atom A to the atom B via a neighboring atom on X is referred to as AˆB, and a linear distance between the atom A and the atom B is referred to as A−B.

39. An organic compound according to claim 3, wherein A−B is 2 Å to 50 Å and (AˆB)/(A−B) is 1.1 to 10, wherein an atom in EM bonded to X is referred to as an atom A, an atom in CTM bonded to X is referred to as an atom B, a shortest distance sum of interatomic distances from the atom A to the atom B via a neighboring atom on X is referred to as AˆB, and a linear distance between the atom A and the atom B is referred to as A−B.

40. An organic compound according to claim 2, wherein said X includes a cycloaliphatic compound.

41. An organic compound according to claim 3, wherein said X includes a cycloaliphatic compound.

42. An organic compound according to claim 2, wherein said X includes a cycloaliphatic compound selected from a group consisting of cycloaliphatic compounds represented by the following general formula (4):

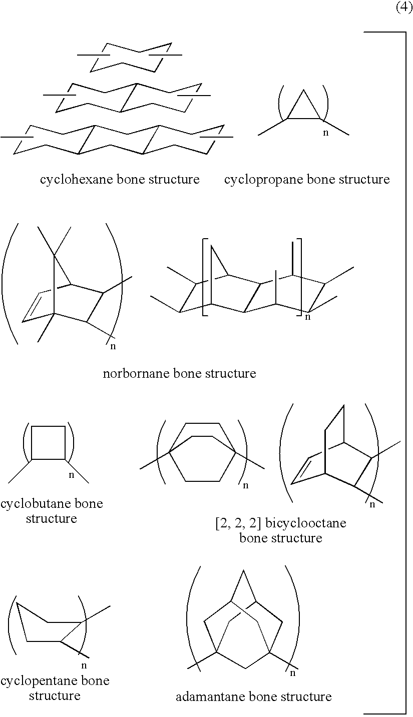

43. An organic compound according to claim 3, wherein said X includes a cycloaliphatic compound selected from a group consisting of cycloaliphatic compounds represented by the following general formula (4):

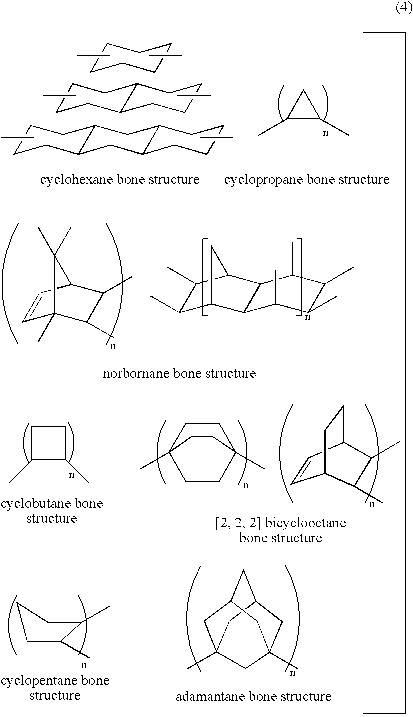

44. An organic compound according to claim 2, wherein said X comprises a hydrocarbon chain containing no hetero atom.

45. An organic compound according to claim 3, wherein said X comprises a hydrocarbon chain containing no hetero atom.

46. An organic compound according to claim 2, wherein said EM is a fluorescent light emission colorant selected from a group consisting of a coumarin derivative, a quinolidine derivative, a quinacridon derivative, a pyrrolopyrrole derivative, a polycyclic aromatic hydrocarbon, a styrylbenzene derivative, polymethine derivative and a xanthene derivative; a fluorescent light emission metallic complex selected from a group consisting of a quinolinol complex derivative, a quinoline complex derivative, a hydroxyphenyl oxazole, a hydroxyphenyl thiazole and an azomethine metallic complex derivative; or a phosphorescent light emission transition metal complex selected from a group consisting of an iridium complex derivative and a platinum complex derivative.

47. An organic compound according to claim 3, wherein said EM is a fluorescent light emission colorant selected from a group consisting of a coumarin derivative, a quinolidine derivative, a quinacridon derivative, a pyrrolopyrrole derivative, a polycyclic aromatic hydrocarbon, a styrylbenzene derivative, polymethine derivative and a xanthene derivative; a fluorescent light emission metallic complex selected from a group consisting of a quinolinol complex derivative, a quinoline complex derivative, a hydroxyphenyl oxazole, a hydroxyphenyl thiazole and an azomethine metallic complex derivative; or a phosphorescent light emission transition metal complex selected from a group consisting of an iridium complex derivative and a platinum complex derivative.

48. An organic compound according to claim 2, wherein said CTM is a hole transporting material selected from a group consisting of an aromatic tertiary amine derivative, starburst polyamines and a phthalocyanine metallic complex derivative; a charge transporting material selected from a group consisting of an aluminoquinolinol complex derivative, an oxadiazole derivative, a triazole derivative, a triazine derivative and a phenylquinoxalline derivative; or a hole charge transporting material selected from a carbazole biphenyl derivative.

49. An organic compound according to claim 3, wherein said CTM is a hole transporting material selected from a group consisting of an aromatic tertiary amine derivative, starburst polyamines and a phthalocyanine metallic complex derivative; a charge transporting material selected from a group consisting of an aluminoquinolinol complex derivative, an oxadiazole derivative, a triazole derivative, a triazine derivative and a phenylquinoxalline derivative; or a hole charge transporting material selected from a carbazole biphenyl derivative.

50. An organic electroluminescent element according to claim 15, wherein the compound is mixed with or dispersed within a charge transporting low or high molecular weight material to form a light emitting layer.

51. An organic electroluminescent element according to claim 16, wherein the compound is mixed with or dispersed within a charge transporting low or high molecular weight material to form a light emitting layer.

52. An organic electroluminescent element according to claim 15, wherein a charge transporting layer is disposed between the organic compound layer and a negative electrode.

53. An organic electroluminescent element according to claim 16, wherein a charge transporting layer is disposed between the organic compound layer and a negative electrode.

54. An organic electroluminescent element according to claim 15, wherein a hole transporting layer is disposed between the organic compound layer and a positive electrode.

55. An organic electroluminescent element according to claim 16, wherein a hole transporting layer is disposed between the organic compound layer and a positive electrode.
